(19) United States
(12) Patent Application Publication
(10) Pub. No.: US 2024/0194660 A1
(43) Pub. Date: Jun. 13, 2024

(54) SEMICONDUCTOR APPARATUS AND METHOD FOR MANUFACTURING SEMICONDUCTOR APPARATUS

(71) Applicant: ROHM CO., LTD., Kyoto-shi (JP)

(72) Inventors: Yoshizo OSUMI, Kyoto-shi (JP); Taro NISHIOKA, Kyoto-shi (JP); Hiroaki MATSUBARA, Kyoto-shi (JP)

(21) Appl. No.: 18/587,461

(22) Filed: Feb. 26, 2024

Related U.S. Application Data
(63) Continuation of application No. PCT/JP2022/029515, filed on Aug. 1, 2022.

(30) Foreign Application Priority Data
Aug. 30, 2021 (JP) 2021-139780

(51) Int. Cl. H01L 25/16; H01L 31/02; H01L 31/0203; H01L 31/18; H01L 33/56; H01L 33/62

(52) U.S. Cl. CPC H01L 25/167; H01L 31/02005; H01L 31/0203; H01L 33/56; H01L 33/62; H01L 31/18; H01L 2933/005; H01L 2933/0066

(57) ABSTRACT

Semiconductor device includes first lead, second lead, light-emitting element, light-receiving element, transparent resin and first resin. First lead includes first die pad having first obverse surface and first reverse surface mutually opposite in thickness direction. Second lead includes second die pad having second obverse surface facing same side as first obverse surface in thickness direction and second reverse surface facing same side as first reverse surface in thickness direction. Light-emitting element is mounted on first obverse surface. Light-receiving element is mounted on second obverse surface. Transparent resin covers portions of light-emitting element and light-receiving element. First resin covers transparent resin. Transparent resin includes transparent-resin obverse surface facing same side as first obverse surface in thickness direction, and transparent-resin reverse surface facing same side as first reverse surface in thickness direction. Transparent-resin reverse surface has surface roughness larger than that of transparent-resin obverse surface.

### TECHNICAL FIELD

The present disclosure relates to a semiconductor device and a method for manufacturing a semiconductor device.

### BACKGROUND ART

An optical semiconductor module has been conventionally known that transmits a signal with a light-emitting element emitting light and a light-receiving element receiving the emitted light. JP 2009-43821 A discloses an example of a conventional optical semiconductor module. The optical semiconductor module disclosed in JP 2009-43821 A includes an input-side lead, an output-side lead, a light-emitting element, a light-receiving element, a transparent resin, and a sealing resin. The light-emitting element is mounted on the input-side lead, and the light-receiving element is mounted on the output-side lead. The transparent resin covers the light-emitting element and the light-receiving element, and the sealing resin covers the transparent resin. The transparent resin is provided by forming a dome covering the light-emitting element and a dome covering the light-receiving element, and connecting these domes with a bridge obtained by potting a transparent resin material with a nozzle while moving the nozzle between the domes. The interface between the lower surface of the bridge of the transparent resin and the sealing resin is flush with (or substantially flush with) the lower surface of the input-side lead and the lower surface of the output-side lead. There is a significant potential difference between the input-side lead and the output-side lead. Furthermore, the dielectric strength at the interface between the resins tends to decrease. The optical semiconductor module described above has low dielectric strength because the interface between the resins is arranged linearly between the leads having significantly different potentials.

### BRIEF DESCRIPTION OF THE DRAWINGS

FIG. 1 is a plan view showing a semiconductor device according to a first embodiment of the present disclosure.

FIG. 2 is a plan view showing the semiconductor device in FIG. 1, with each resin shown transparent.

FIG. 3 is a partially enlarged view of FIG. 2.

FIG. 4 is a front view showing the semiconductor device in FIG. 1.

FIG. 5 is a right-side view showing the semiconductor device in FIG. 1.

FIG. 6 is a cross-sectional view along line VI-VI in FIG. 2.

FIG. 7 is a partially enlarged view of FIG. 6.

FIG. 8 is a partially enlarged cross-sectional view showing a conventional semiconductor device for comparison, and corresponds to FIG. 7.

FIG. 9 is a partially enlarged plan view showing the semiconductor device in FIG. 8, and corresponds to FIG. 3.

FIG. 10 is an example of a flowchart showing a method for manufacturing the semiconductor device in FIG. 1.

FIG. 11 is a partially enlarged cross-sectional view showing a step of the method for manufacturing the semiconductor device in FIG. 1.

FIG. 12 is a partially enlarged cross-sectional view showing a step of the method for manufacturing the semiconductor device in FIG. 1.

FIG. 13 is a partially enlarged cross-sectional view showing a step of the method for manufacturing the semiconductor device in FIG. 1.

FIG. 14 is a partially enlarged cross-sectional view showing a step of the method for manufacturing the semiconductor device in FIG. 1.

FIG. 15 is a partially enlarged cross-sectional view showing a semiconductor device according to a second embodiment of the present disclosure.

FIG. 16 is a partially enlarged cross-sectional view showing a semiconductor device according to a third embodiment of the present disclosure.

FIG. 17 is a partially enlarged cross-sectional view showing a semiconductor device according to a fourth embodiment of the present disclosure.

FIG. 18 is a partially enlarged cross-sectional view showing a semiconductor device according to a fifth embodiment of the present disclosure.

FIG. 19 is a partially enlarged cross-sectional view showing a semiconductor device according to a sixth embodiment of the present disclosure.

FIG. 20 is a partially enlarged plan view showing a semiconductor device according to a seventh embodiment of the present disclosure.

### DETAILED DESCRIPTION OF EMBODIMENTS

The following describes preferred embodiments of the present disclosure in detail with reference to the drawings.

### First Embodiment

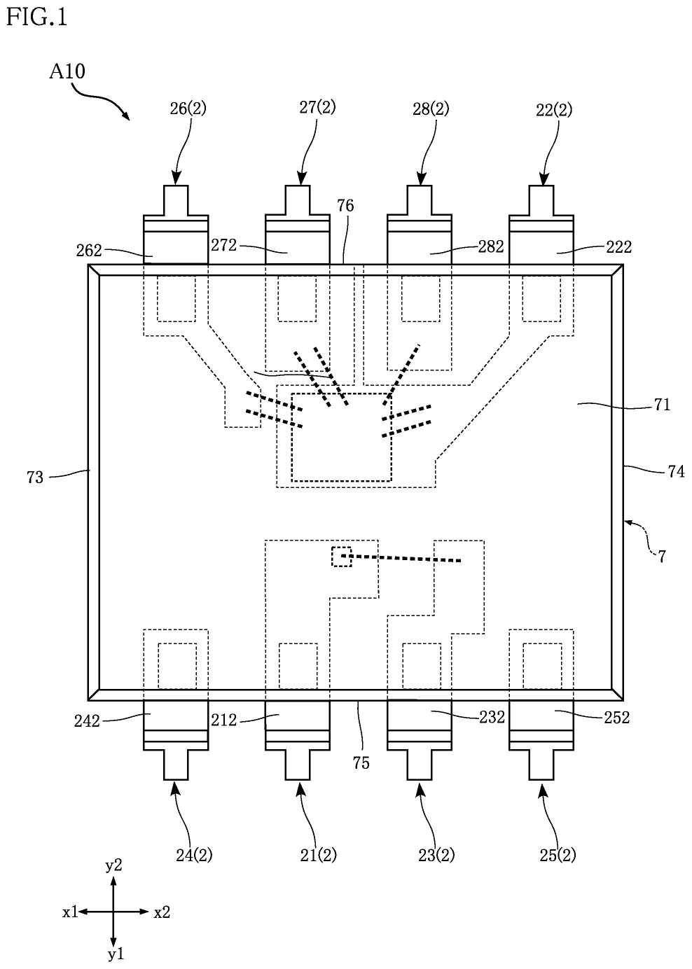

The following describes a semiconductor device A10 according to a first embodiment of the present disclosure, with reference to FIGS. 1 to 7. The semiconductor device A10 includes a light-emitting element 11, a light-receiving element 12, a conductive supporting member 2, a plurality of wires 4, a transparent resin 5, white resins 61 and 62, and a sealing resin 7.

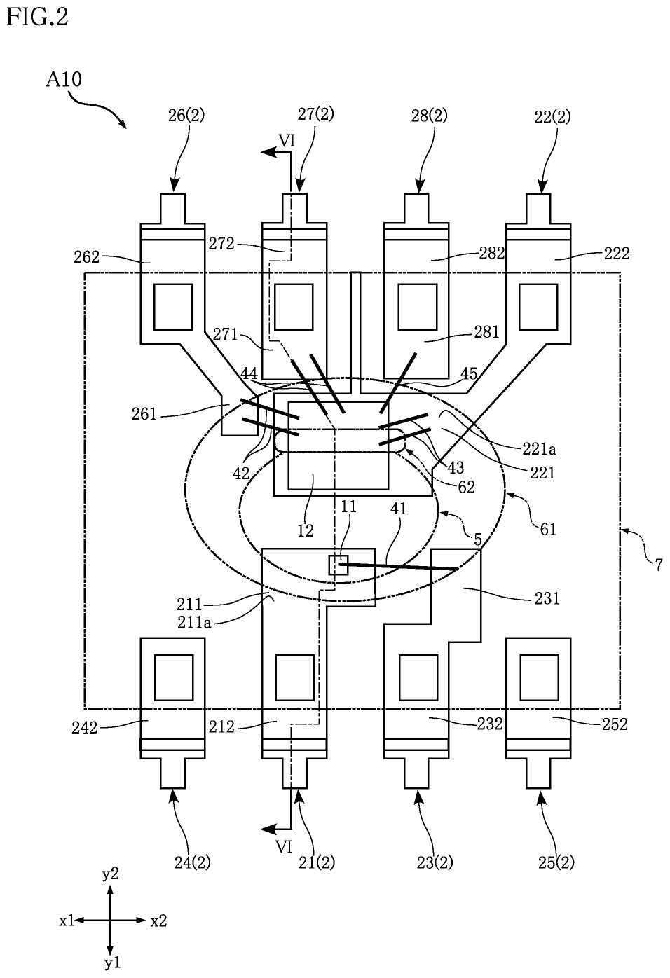

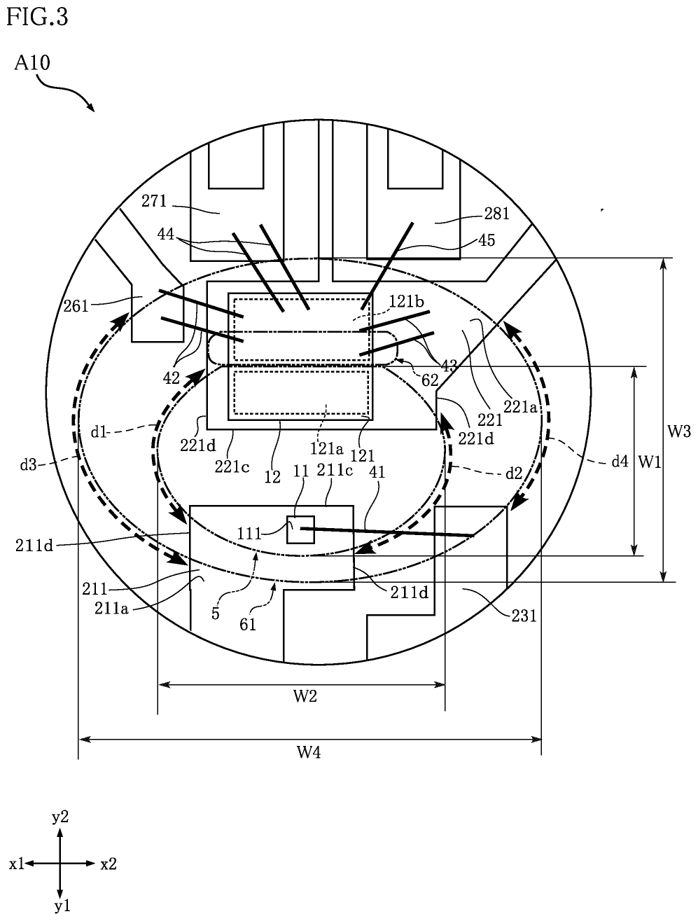

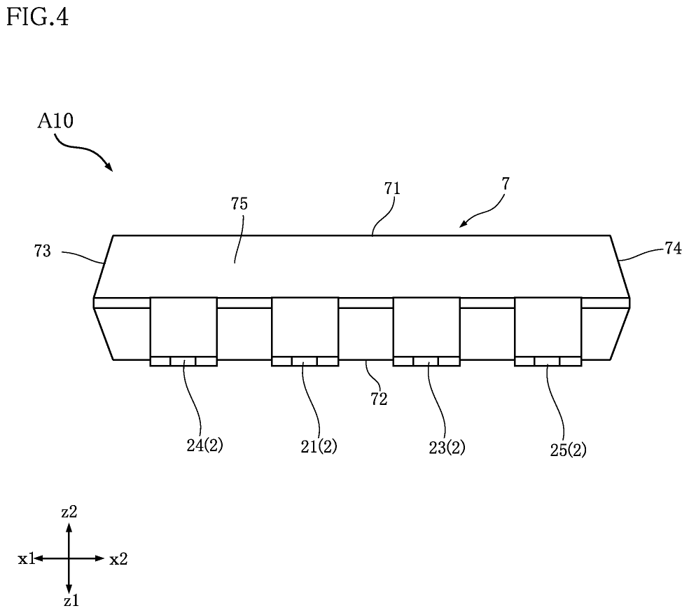

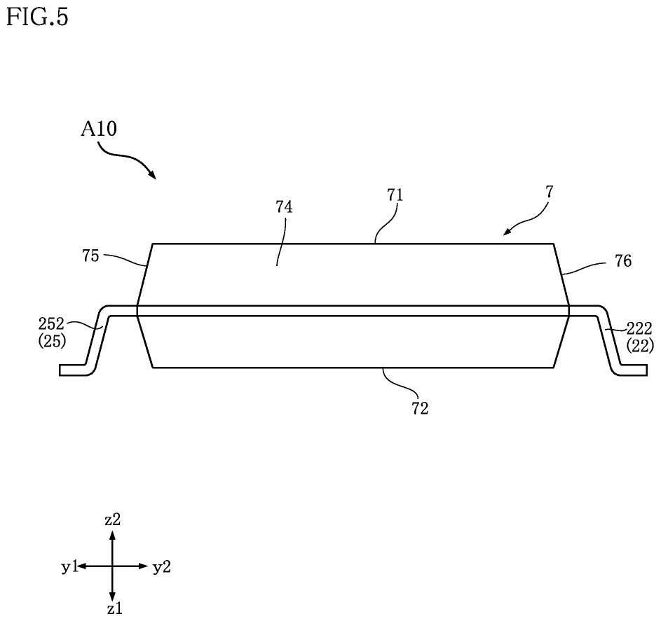

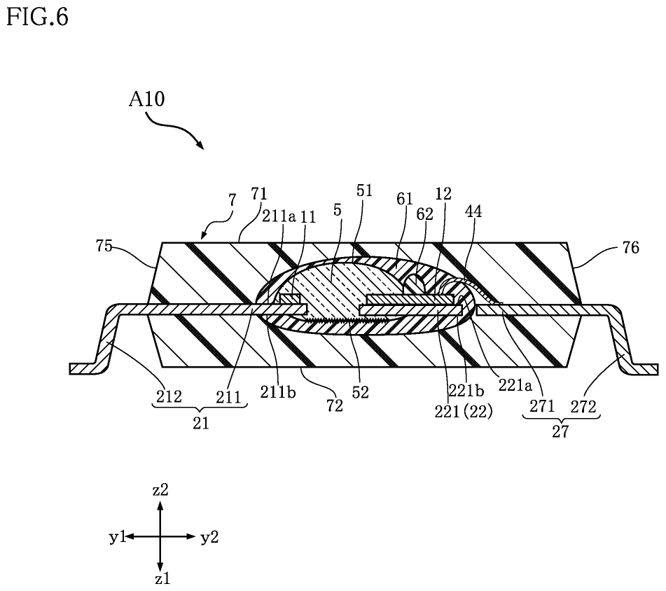

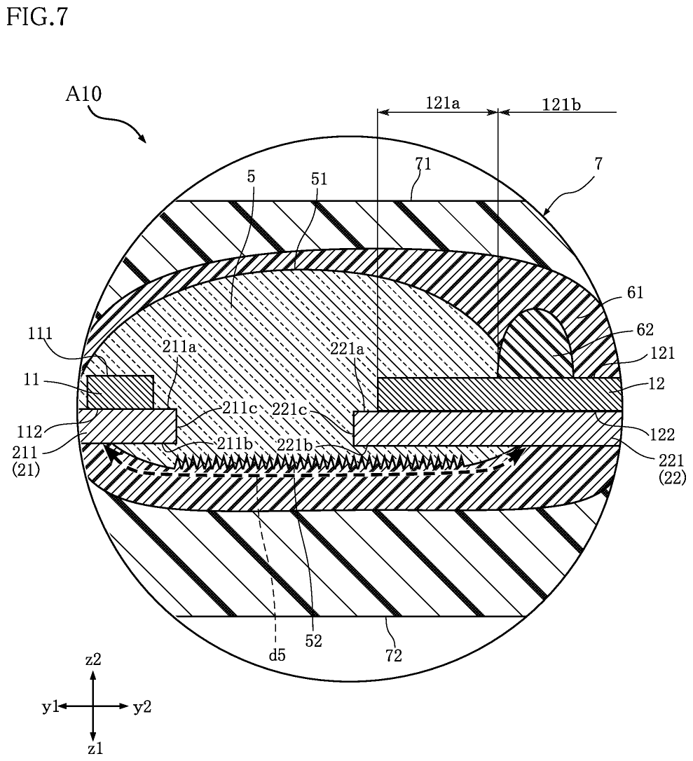

FIG. 1 is a plan view showing the semiconductor device A10. FIG. 2 is a plan view showing the semiconductor device A10. For convenience of understanding, FIG. 2 shows the transparent resin 5, the white resins 61 and 62, and the sealing resin 7 in phantom, and the outer shape of each resin is indicated by an imaginary line (two-dot chain line). FIG. 3 is a partially enlarged view of FIG. 2. FIG. 4 is a front view showing the semiconductor device A10. FIG. 5 is a right-side view showing the semiconductor device A10. FIG. 6 is a cross-sectional view along line VI-VI in FIG. 2. FIG. 7 is a partially enlarged view of FIG. 6.

The semiconductor device A10 shown in these figures is surface-mountable on the circuit boards of various devices. The semiconductor device A10 is not limited to specific applications and/or functions. The semiconductor device A10 is provided in a small outline package (SOP). The packaging of the semiconductor device A10, however, is not limited to SOP. The semiconductor device A10 has a portion covered with the sealing resin 7, and the portion has a rectangular shape as viewed in a thickness direction (in plan view). For convenience, the thickness direction of the semiconductor device A10 is referred to as “z direction”. The direction (vertical direction in FIGS. 1 to 3) in which terminals (such as a terminal section 212 of a lead 21 described below) of the semiconductor device A10 that are perpendicular to the z direction extend is referred to as “y direction”. The direction (horizontal direction in FIGS. 1 to 3) perpendicular to the z direction and the y direction is referred to as “x direction”. The y direction is an example of a “first direction”, and the x direction is an example of a “second direction”. The semiconductor device A10 is not limited to specific dimensions.

The conductive supporting member 2 is a conductive member that forms a conductive path connecting each of the light-emitting element 11 and the light-receiving element 12 to a circuit board on which the semiconductor device A10 is mounted. The conductive supporting member 2 is a portion of a lead frame used in the manufacturing of the semiconductor device A10. The thickness of the conductive supporting member 2 is not particularly limited, but may be approximately 200 μm in one example. The conductive supporting member 2 is preferably made of Cu or Ni, an alloy thereof, or 42 alloy, for example. The conductive supporting member 2 includes leads 21 to 28. The leads 21 to 28 are spaced apart from each other.

The lead 21 supports the light-emitting element 11, and is electrically connected to the light-emitting element 11. The lead 21 includes a first die pad 211 and a terminal section 212.

As shown in FIG. 2, the first die pad 211 is offset in the semiconductor device A10 to the y1 side in the y direction, and is located at the center (or substantially at the center) in the x direction. The first die pad 211 has the light-emitting element 11 mounted thereon. The first die pad 211 is covered with the transparent resin 5, the white resin 61, and the sealing resin 7. The first die pad 211 has a rectangular shape (or substantially rectangular shape) as viewed in the z direction. As shown in FIGS. 3 and 7, the first die pad 211 has an obverse surface 211a, a reverse surface 211b, an opposing surface 211c, and two side surfaces 211d.

As shown in FIGS. 6 and 7, the obverse surface 211a and the reverse surface 211b face away from each other in the z direction. The obverse surface 211a faces the z2 side, and the reverse surface 211b faces the z1 side. The obverse surface 211a and the reverse surface 211b are flat (or substantially flat). The light-emitting element 11 is bonded to the obverse surface 211a. As shown in FIG. 7, the opposing surface 211c is connected to the obverse surface 211a and the reverse surface 211b, and faces the y2 side in the y direction. As shown in FIGS. 3 and 7, the opposing surface 211c faces an opposing surface 221c of a second die pad 221 (described below). As shown in FIG. 3, each of the two side surfaces 211d is connected to the obverse surface 211a, the reverse surface 211b, and the opposing surface 211c. One of the side surfaces 211d faces the x1 side in the x direction, and the other side surface 211d faces the x2 side in the x direction.

As shown in FIG. 2, the terminal section 212 is connected to the first die pad 211 on the y1 side in the y direction, extends toward the y1 side in the y direction, and is partially exposed from the sealing resin 7. The terminal section 212 is electrically connected to the light-emitting element 11 via the first die pad 211. The terminal section 212 has a portion covered with the sealing resin 7, and the portion has a through-hole formed therethrough in the z direction. The through-hole is provided to improve the adhesion between the lead 21 and the sealing resin 7. As shown in FIG. 6, the portion of the terminal section 212 exposed from the sealing resin 7 is bent into a hook shape as viewed in the x direction. The shape of the lead 21 is not limited to the one described above.

The lead 23 is electrically connected to the light-emitting element 11. The lead 23 includes a pad section 231 and a terminal section 232.

As shown in FIG. 2, the pad section 231 is arranged on the x2 side in the x direction relative to the first die pad 211. The pad section 231 is electrically connected to the light-emitting element 11 via a wire 4 (a wire 41 described below). The pad section 231 is covered with the white resin 61 and the sealing resin 7. The pad section 231 has a rectangular shape (or substantially rectangular shape) as viewed in the z direction. The pad section 231 has a surface facing the z2 side in the z direction, and the wire 41 is bonded to the surface.

As shown in FIG. 2, the terminal section 232 is connected to the pad section 231 on the y1 side in the y direction, extends toward the y1 side in the y direction, and is partially exposed from the sealing resin 7. The terminal section 232 is electrically connected to the light-emitting element 11 via the pad section 231 and the wire 41. The terminal section 232 has a portion covered with the sealing resin 7, and the portion has a through-hole formed therethrough in the z direction. The through-hole is provided to improve the adhesion between the lead 23 and the sealing resin 7. The portion of the terminal section 232 exposed from the sealing resin 7 is bent into a hook shape as viewed in the x direction. The shape of the lead 23 is not limited to the one described above.

The lead 24 is a so-called dummy terminal, and is arranged on the x1 side in the x direction relative to the lead 21. The lead 24 includes a terminal section 242. As shown in FIG. 2, the terminal section 242 extends toward the y1 side in the y direction, and is partially exposed from the sealing resin 7. The terminal section 242 has a portion covered with the sealing resin 7, and the portion has a through-hole formed therethrough in the z direction. The through-hole is provided to improve the adhesion between the lead 24 and the sealing resin 7. The portion of the terminal section 242 exposed from the sealing resin 7 is bent into a hook shape as viewed in the x direction. The shape of the lead 24 is not limited to the one described above.

The lead 25 is a so-called dummy terminal, and is arranged on the x2 side in the x direction relative to the lead 23. The lead 25 includes a terminal section 252. As shown in FIG. 2, the terminal section 252 extends toward the y1 side in the y direction, and is partially exposed from the sealing resin 7. The terminal section 252 has a portion covered with the sealing resin 7, and the portion has a through-hole formed therethrough in the z direction. The through-hole is provided to improve the adhesion between the lead 25 and the sealing resin 7. As shown in FIG. 5, the portion of the terminal section 252 exposed from the sealing resin 7 is bent into a hook shape as viewed in the x direction. The shape of the lead 25 is not limited to the one described above.

As shown in FIG. 1, the terminal sections 242, 212, 232, and 252 protrude from the surface (resin side surface 75 described below) of the sealing resin 7 on the y1 side in the y direction, and are arranged side by side at equal intervals in this order from the x1 side to the x2 side in the x direction.

The lead 22 supports the light-receiving element 12, and is electrically connected to the light-receiving element 12. The lead 22 includes a second die pad 221 and a terminal section 222.

As shown in FIG. 2, the second die pad 221 is offset in the semiconductor device A10 to the y2 side in the y direction, and is located at the center (or substantially at the center) in the x direction. The second die pad 221 has the light-receiving element 12 mounted thereon. The second die pad 221 is electrically connected to the light-receiving element 12 via a wire 4 (a wire 43 described below). The second die pad 221 is covered with the transparent resin 5 and the white resins 61 and 62. The second die pad 221 has a rectangular shape (or substantially rectangular shape) as viewed in the z direction. As shown in FIGS. 3 and 7, the second die pad 221 has an obverse surface 221a, a reverse surface 221b, an opposing surface 221c, and two side surfaces 221d.

As shown in FIGS. 6 and 7, the obverse surface 221a and the reverse surface 221b face away from each other in the z direction. The obverse surface 221a faces the z2 side, and the reverse surface 221b faces the z1 side. The obverse surface 211a and the reverse surface 211b are flat (or substantially flat). The light-receiving element 12 is bonded to the obverse surface 221a. As shown in FIG. 7, the opposing surface 221c is connected to the obverse surface 221a and the reverse surface 221b, and faces the y1 side in the y direction. As shown in FIGS. 3 and 7, the opposing surface 221c faces the opposing surface 211c of the first die pad 211. As shown in FIG. 3, each of the two side surfaces 221d is connected to the obverse surface 221a, the reverse surface 221b, and the opposing surface 221c. One of the side surfaces 221d faces the x1 side in the x direction, and the other side surface 221d faces the x2 side in the x direction.

As shown in FIG. 2, the terminal section 222 is connected to the second die pad 221 on the x2 side in the x direction, extends toward the y2 side in the y direction, and is partially exposed from the sealing resin 7. The terminal section 222 is electrically connected to the light-receiving element 12 via the second die pad 221 and the wire 43. The terminal section 222 has a portion covered with the sealing resin 7, and the portion has a through-hole formed therethrough in the z direction. The through-hole is provided to improve the adhesion between the lead 22 and the sealing resin 7. As shown in FIG. 5, the portion of the terminal section 222 exposed from the sealing resin 7 is bent into a hook shape as viewed in the x direction. The shape of the lead 22 is not limited to the one described above.

The lead 26 is electrically connected to the light-receiving element 12. The lead 26 includes a pad section 261 and a terminal section 262.

As shown in FIG. 2, the pad section 261 is arranged on the x1 side in the x direction relative to the second die pad 221. The pad section 261 is electrically connected to the light-receiving element 12 via a wire 4 (a wire 42 described below). The pad section 261 is covered with the white resin 61 and the sealing resin 7. The pad section 261 has a rectangular shape (or substantially rectangular shape) as viewed in the z direction. The pad section 261 has a surface facing the z2 side in the z direction, and the wire 42 is bonded to the surface.

As shown in FIG. 2, the terminal section 262 is connected to the pad section 261 on the y2 side in the y direction, extends toward the y2 side in the y direction, and is partially exposed from the sealing resin 7. The terminal section 262 is electrically connected to the light-receiving element 12 via the pad section 261 and the wire 42. The terminal section 262 has a portion covered with the sealing resin 7, and the portion has a through-hole formed therethrough in the z direction. The through-hole is provided to improve the adhesion between the lead 26 and the sealing resin 7. The portion of the terminal section 262 exposed from the sealing resin 7 is bent into a hook shape as viewed in the x direction. The shape of the lead 26 is not limited to the one described above.

The lead 27 is electrically connected to the light-receiving element 12. The lead 27 includes a pad section 271 and a terminal section 272.

As shown in FIG. 2, the pad section 271 is arranged on the y2 side in the y direction relative to the second die pad 221. The pad section 271 is electrically connected to the light-receiving element 12 via a wire 4 (a wire 44 described below). The pad section 271 is covered with the sealing resin 7. The pad section 271 has a rectangular shape (or substantially rectangular shape) as viewed in the z direction. The pad section 271 has a surface facing the z2 side in the z direction, and the wire 44 is bonded to the surface.

As shown in FIG. 2, the terminal section 272 is connected to the pad section 271 on the y2 side in the y direction, extends toward the y2 side in the y direction, and is partially exposed from the sealing resin 7. The terminal section 272 is electrically connected to the light-receiving element 12 via the pad section 271 and the wire 44. The terminal section 272 has a portion covered with the sealing resin 7, and the portion has a through-hole formed therethrough in the z direction. The through-hole is provided to improve the adhesion between the lead 27 and the sealing resin 7. The portion of the terminal section 272 exposed from the sealing resin 7 is bent into a hook shape as viewed in the x direction. The shape of the lead 27 is not limited to the one described above.

The lead 28 is electrically connected to the light-receiving element 12. The lead 28 includes a pad section 281 and a terminal section 282.

As shown in FIG. 2, the pad section 281 is arranged on the y2 side in the y direction relative to the second die pad 221, and on the x2 side in the x direction relative to the pad section 271. The pad section 281 is electrically connected to the light-receiving element 12 via a wire 4 (a wire 45 described below). The pad section 281 is covered with the sealing resin 7. The pad section 281 has a rectangular shape (or substantially rectangular shape) as viewed in the z direction. The pad section 281 has a surface facing the z2 side in the z direction, and the wire 45 is bonded to the surface.

As shown in FIG. 2, the terminal section 282 is connected to the pad section 281 on the y2 side in the y direction, extends toward the y2 side in the y direction, and is partially exposed from the sealing resin 7. The terminal section 282 is electrically connected to the light-receiving element 12 via the pad section 281 and the wire 45. The terminal section 282 has a portion covered with the sealing resin 7, and the portion has a through-hole formed therethrough in the z direction. The through-hole is provided to improve the adhesion between the lead 28 and the sealing resin 7. The portion of the terminal section 282 exposed from the sealing resin 7 is bent into a hook shape as viewed in the x direction. The shape of the lead 28 is not limited to the one described above.

As shown in FIG. 1, the terminal sections 262, 272, 282, and 222 protrude from the surface (resin side surface 76 described below) of the sealing resin 7 on the y2 side in the y direction, and are arranged side by side at equal intervals in this order from the x1 side to the x2 side in the x direction.

The portions of the leads 21 to 28 exposed from the sealing resin 7 may be formed with a plating layer made of an alloy mainly containing Sn, for example. The region of the obverse surface 211a of the first die pad 211 to which the light-emitting element 11 is bonded, the region of the obverse surface 221a of the second die pad 221 to which the light-receiving element 12 or the wire 43 is bonded, and the regions of the pad sections 231, 261, 271, and 281 to which the wires 4 are bonded may be formed with plating layers made of Ag, for example.

The light-emitting element 11 is an LED chip, for example, and is configured to emit light having a constant wavelength. The light-emitting element 11 includes a semiconductor material. The light-emitting element 11 has a rectangular plate shape as viewed in the z direction. As shown in FIG. 7, the light-emitting element 11 has an obverse surface 111 and a reverse surface 112. The obverse surface 111 and the reverse surface 112 face away from each other in the z direction. The obverse surface 111 faces the z2 side in the z direction. The reverse surface 112 faces the z1 side in the z direction. The light-emitting element 11 includes a cathode electrode (not illustrated) arranged on the obverse surface 111, and an anode electrode (not illustrated) arranged on the reverse surface 112.

As shown in FIG. 7, the light-emitting element 11 is bonded to the obverse surface 211a of the first die pad 211 via a non-illustrated bonding material. The bonding material is electrically conductive, for example, and may be, but not limited to, solder. The reverse surface 112 of the light-emitting element 11 is bonded to the obverse surface 211a of the first die pad 211 via the bonding material. The anode electrode of the light-emitting element 11 is electrically connected to the first die pad 211 via the bonding material. As a result, the terminal section 212 of the lead 21 is electrically connected to the anode electrode of the light-emitting element 11 to function as an anode terminal. As shown in FIG. 3, the cathode electrode of the light-emitting element 11 is electrically connected to the pad section 231 of the lead 23 via the wire 41. As a result, the terminal section 232 of the lead 23 is electrically connected to the cathode electrode of the light-emitting element 11 to function as a cathode terminal.

The light-emitting element 11 is entirely covered with the transparent resin 5. The light-emitting element 11 emits light in response to the current that flows when voltage is applied across the anode electrode and the cathode electrode. The light emitted by the light-emitting element 11 travels through the transparent resin 5. Since the entirety of the light-emitting element 11 is covered with the transparent resin 5, the light emitted by the light-emitting element 11 is efficiently transmitted to the light-receiving element 12.

The light-receiving element 12 receives the light emitted by the light-emitting element 11. The light-receiving element 12 includes a semiconductor material. The light-receiving element 12 has a rectangular plate shape as viewed in the z direction. As shown in FIG. 7, the light-receiving element 12 has an obverse surface 121 and a reverse surface 122. The obverse surface 121 and the reverse surface 122 face away from each other in the z direction. The obverse surface 121 faces the z2 side in the z direction. The reverse surface 122 faces the z1 side in the z direction.

As shown in FIG. 7, the light-receiving element 12 is bonded to the obverse surface 221a of the second die pad 221 via a non-illustrated bonding material. Although not particularly limited, the bonding material may be an insulating bonding material. The reverse surface 122 of the light-receiving element 12 is bonded to the obverse surface 221a of the second die pad 221 via the bonding material. The light-emitting element 11 and the light-receiving element 12 are aligned in the y direction.

As shown in FIGS. 3 and 7, a light-receiving section 121a and a circuit forming section 121b are arranged on the obverse surface 121 of the light-receiving element 12. The light-receiving section 121a is offset to the y1 side in the y direction on the obverse surface 121. The light-receiving section 121a includes a photodiode, for example, and generates an electromotive force corresponding to the amount of received light. On the obverse surface 121 of the light-receiving element 12, the region where the light-receiving section 121a is arranged is entirely covered with the transparent resin 5. As a result, the light-receiving section 121a can receive light appropriately from the light-emitting element 11 via the transparent resin 5.

The circuit forming section 121b is offset from the center of the obverse surface 121 in the y direction to the y2 side. The circuit forming section 121b is formed with a circuit that includes, for example, a transistor. The circuit forming section 121b amplifies and outputs the electromotive force generated by the light-receiving section 121a receiving light. The circuit forming section 121b is provided with a plurality of electrodes. As shown in FIG. 3, the electrodes are electrically connected to the leads 22, 26, 27, and 28 via wires 4. Specifically, a power-supply electrode of the light-receiving element 12 is electrically connected to the pad section 261 of the lead 26 via the wire 42. As a result, the terminal section 262 of the lead 26 is electrically connected to the power-supply electrode of the light-receiving element 12 to function as a power-supply terminal. A ground electrode of the light-receiving element 12 is electrically connected to the second die pad 221 via the wire 43. As a result, the terminal section 222 of the lead 22 is electrically connected to the ground electrode of the light-receiving element 12 to function as a ground terminal. An output electrode of the light-receiving element 12 is electrically connected to the pad section 271 of the lead 27 via the wire 44. As a result, the terminal section 272 of the lead 27 is electrically connected to the output electrode of the light-receiving element 12 to function as an output terminal. The light-receiving element 12 has an undervoltage lockout function that stops the output when the source voltage drops. The light-receiving element 12 includes a detection electrode that outputs a low-voltage detection signal indicating a drop of the source voltage. The detection electrode is electrically connected to the pad section 281 of the lead 28 via the wire 45. As a result, the terminal section 282 of the lead 28 is electrically connected to the detection electrode of the light-receiving element 12 to function as a detection terminal.

On the obverse surface 121 of the light-receiving element 12, the region where the circuit forming section 121b is arranged is exposed from the transparent resin 5 and entirely covered with either the white resin 61 or 62. As a result, the circuit forming section 121b is not irradiated with the light emitted by the light-emitting element 11.

When voltage is applied across the terminal section 212 and the terminal section 222, the voltage is applied across the anode electrode and the cathode electrode of the light-emitting element 11 to cause a current to flow, thus causing the light-emitting element 11 to emit light. Upon receiving light, the light-receiving section 121a of the light-receiving element 12 generates an electromotive force corresponding to the amount of the received light. The electromotive force is amplified, in the circuit forming section 121b, by the power supplied between the terminal section 262 and the terminal section 222, and is outputted from the terminal section 272. In this way, the semiconductor device A10 can transmit a signal from an input side (the terminal sections 212 and 232) to an output side (the terminal section 272) with the input side and the output side being electrically insulated from each other.

As shown in FIGS. 2 and 3, the wires 4 are conductive members that form a conductive path connecting the light-emitting element 11 and the light-receiving element 12 to a circuit board, together with the conductive supporting member 2. Each of the wires 4 is made of a metal containing Au, Cu, or Al, for example. The wires 4 include the wires 41 to 45.

The wire 41 forms a conductive path between the light-emitting element 11 and the lead 23. The wire 41 is bonded to the cathode electrode of the light-emitting element 11 and the pad section 231 of the lead 23. Note that the number of wires 41 is not particularly limited. The wire 42 forms a conductive path between the light-receiving element 12 and the lead 26. The wire 42 is bonded to the power-supply electrode of the light-receiving element 12 and the pad section 261 of the lead 26. Note that the number of wires 42 is not particularly limited. The wire 43 forms a conductive path between the light-receiving element 12 and the lead 22. The wire 43 is bonded to the ground electrode of the light-receiving element 12 and the second die pad 221. Note that the number of wires 43 is not particularly limited. The wire 44 forms a conductive path between the light-receiving element 12 and the lead 27. The wire 44 is bonded to the output electrode of the light-receiving element 12 and the pad section 271 of the lead 27. Note that the number of wires 44 is not particularly limited. The wire 45 forms a conductive path between the light-receiving element 12 and the lead 28. The wire 45 is bonded to the detection electrode of the light-receiving element 12 and the pad section 281 of the lead 28. Note that the number of wires 45 is not particularly limited.

As shown in FIGS. 3 and 7, the transparent resin 5 covers a portion of the conductive supporting member 2, the entirety of the light-emitting element 11, a portion of the light-receiving element 12 (a portion where the light-receiving section 121a is arranged), and a portion of the wire 41. The transparent resin 5 is electrically insulative. The transparent resin 5 contains a transparent epoxy resin, for example. The constituent material of the transparent resin 5 is not particularly limited as long as the material transmits light. As described below, the transparent resin 5 is formed by placing a mold on a lead frame that will be formed into the conductive supporting member 2, specifically the surface of the lead frame on the z1 side in the z direction, and potting the material of the transparent resin 5 from the z2 side in the z direction.

As shown in FIG. 7, the transparent resin 5 has a dome shape bulging to the z2 side in the z direction. The transparent resin 5 includes a portion located on the z1 side in the z direction relative to the reverse surface 211b and the reverse surface 221b, between the first die pad 211 and the second die pad 221 as viewed in the z direction. Furthermore, the transparent resin 5 covers a portion of each of the reverse surface 211b and the reverse surface 221b. Note that the transparent resin 5 may cover the entirety of each of the reverse surface 211b and the reverse surface 221b. The transparent resin 5 has a first portion formed on the z1 side in the z direction relative to the conductive supporting member 2, and a second portion formed on the z2 side in the z direction relative to the conductive supporting member 2, and the maximum value of the height (dimension in the z direction) of the first portion with respect to the conductive supporting member 2 is sufficiently small as compared to the maximum value (dimension in the z direction) of the height of the second portion with respect to the conductive supporting member 2. In other words, the transparent resin 5 is formed to be thicker on the z2 side in the z direction relative to the conductive supporting member 2, and is formed to be thinner on the z1 side in the z direction relative to the conductive supporting member 2. The first portion of the transparent resin 5, which is formed on the z1 side in the z direction relative to the conductive supporting member 2, is formed by the mold, so that the first portion is formed into a predetermined shape.

As shown in FIG. 7, the transparent resin 5 has a transparent-resin obverse surface 51 and a transparent-resin reverse surface 52. The transparent-resin obverse surface 51 and the transparent-resin reverse surface 52 face away from each other in the z direction. The transparent-resin obverse surface 51 faces the z2 side in the z direction, and the transparent-resin reverse surface 52 faces the z1 side in the z direction. The transparent-resin obverse surface 51 is a curved surface having a dome shape bulging to the z2 side in the z direction. The transparent-resin reverse surface 52 is the surface of the portion located on the z1 side in the z direction relative to the reverse surface 211b and the reverse surface 221b (the portion including the portion covering the reverse surface 211b and the reverse surface 221b). The transparent-resin reverse surface 52 has irregularities formed thereon. The shape, arrangement, and degree of the irregularities are not particularly limited. The irregularities are formed by irregularities formed in the mold. On the other hand, the transparent-resin obverse surface 51 is smooth because it is formed by the surface tension of the material of the transparent resin 5 in potting. Accordingly, the transparent-resin reverse surface 52 has a surface roughness larger than the transparent-resin obverse surface 51.

As shown in FIG. 3, the transparent resin 5 has an elliptical (or substantially elliptical) shape elongated in the x direction as viewed in the z direction. It is preferable that the transparent resin 5 have a dimension W1 in the y direction that is relatively small, and a dimension W2 in the x direction that is relatively large. It is preferable that the dimension W2 be larger than the dimension W1, and is more preferable that the dimension W2 be at least 1.5 times larger than the dimension W1. The transparent resin 5 entirely covers the opposing surface 211c of the first die pad 211 and the opposing surface 221c of the second die pad 221. As viewed in the z direction, the interface between the transparent resin 5 and the white resin 61 protrudes outward from the two side surfaces 211d of the first die pad 211.

The white resins 61 and 62 are electrically insulative, and may be silicone resin colored in white. The constituent material of the white resins 61 and 62 is not particularly limited. The white resin 61 covers the entirety of the transparent resin 5. The light emitted by the light-emitting element 11 is reflected at the interface between the transparent resin 5 and the white resin 61, and travels through the transparent resin 5. As shown in FIG. 3, the white resin 61 has an elliptical (or substantially elliptical) shape elongated in the x direction as viewed in the z direction. It is preferable that the white resin 61 have a dimension W4 in the x direction that is relatively large. It is preferable that the dimension W4 be larger than a dimension W3 that is a dimension in the y direction, and is more preferable that the dimension W4 be at least 1.5 times larger than the dimension W3. The white resin 61 entirety covers the two side surfaces 221d of the second die pad 221. The white resin 61 is formed by potting the material of the white resin 61 to cover the entirety of the transparent resin 5. The surface of the white resin 61 is smooth because it is formed by the surface tension of the material of the white resin 61 in potting.

The white resin 62 is in contact with the obverse surface 121 of the light-receiving element 12, and covers a portion of the obverse surface 121 which is located at the center (or substantially at the center) of the obverse surface 121 in the y direction and extends over the entire length of the obverse surface 121 in the x direction. The white resin 62 is formed on the circuit forming section 121b so as not to cover the light-receiving section 121a. The white resin 62 is in contact with both of the transparent resin 5 and the white resin 61. The white resin 62 is formed by potting the material of the white resin 62. The white resin 62 is formed before the formation of the transparent resin 5, so that the white resin 62 stops the flow of the fluidized material of the transparent resin 5 during the formation of the transparent resin 5. As such, the transparent resin 5 is formed to cover the light-receiving section 121a and not to cover the circuit forming section 121b. The white resin 61 and the white resin 62 are preferably, but not necessarily, made of the same material.

It is possible to use a non-white resin instead of the white resins 61 and 62. The color of the resin is not limited as long as the light emitted by the light-emitting element 11 is reflected by the resin at the interface between the resin and the transparent resin 5. However, it is desirable that the resin be white so as to efficiently reflect the emitted light.

The sealing resin 7 covers a portion of the conductive supporting member 2 and the entirety of each of the light-emitting element 11, the light-receiving element 12, the wires 4, the transparent resin 5, and the white resins 61 and 62. The sealing resin 7 is electrically insulative. The sealing resin 7 contains a black epoxy resin, for example. The constituent material of the sealing resin 7 is not particularly limited. The sealing resin 7 is formed by transfer molding using a mold, for example. As viewed in the z direction, the sealing resin 7 has a rectangular shape.

The sealing resin 7 includes a resin top surface 71, a resin bottom surface 72, and resin side surfaces 73 to 76. The resin top surface 71 and the resin bottom surface 72 face away from each other in the z direction. The resin top surface 71 faces the z2 side in the z direction, and the resin bottom surface 72 faces the z1 side in the z direction. The resin top surface 71 and the resin bottom surface 72 are flat (or substantially flat).

The resin side surfaces 73 to 76 are connected to the resin top surface 71 and the resin bottom surface 72, and are located between the resin top surface 71 and the resin bottom surface 72 in the z direction. The resin side surface 73 and the resin side surface 74 face away from each other in the x direction. The resin side surface 73 faces the x1 side in the x direction, and the resin side surface 74 faces the x2 side in the x direction. The resin side surface 75 and the resin side surface 76 face away from each other in the y direction. The resin side surface 75 faces the y1 side in the y direction, and the resin side surface 76 faces the y2 side in the y direction. As shown in FIG. 1, a portion of each of the terminal sections 242, 212, 232, and 252 protrudes from the resin side surface 75. A portion of each of the terminal sections 262, 272, 282, and 222 protrudes from the resin side surface 76. The conductive supporting member 2 is not exposed from the resin side surface 73 or the resin side surface 74.

As shown in FIGS. 4 and 5, the resin side surfaces 73 to 76 include respective inclined surface portions connected to the resin top surface 71 and inclined to become closer to each other as proceeding to the resin top surface 71. In other words, the sealing resin 7 includes a part surrounded by the inclined surface portions connected to the resin obverse surface 71, and this part has a tapered shape whose cross-sectional area in the xy plane decreases toward the resin obverse surface 71. Likewise, the resin side surfaces 73 to 76 include respective inclined surface portions connected to the resin reverse surface 72 and inclined to become closer to each other as proceeding to the resin reverse surface 72. In other words, the sealing resin 7 includes a part surrounded by the inclined surface portions connected to the resin reverse surface 72, and this part has a tapered shape whose cross-sectional area in the xy plane decreases toward the resin reverse surface 72. Note that the shape of the sealing resin 7 shown in FIGS. 1, 4, and 5 is merely an example. The shape of the sealing resin 7 is not limited to the illustrated example.

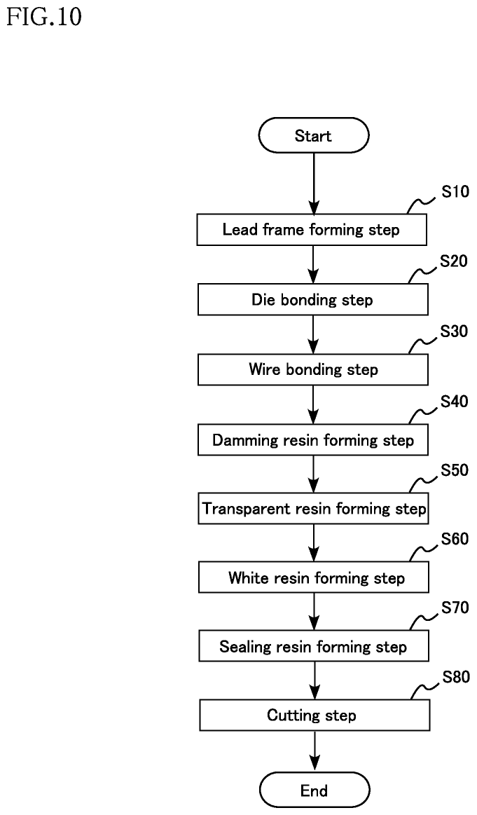

Next, an example of a method for manufacturing the semiconductor device A10 will be described with reference to FIGS. 10 to 14.

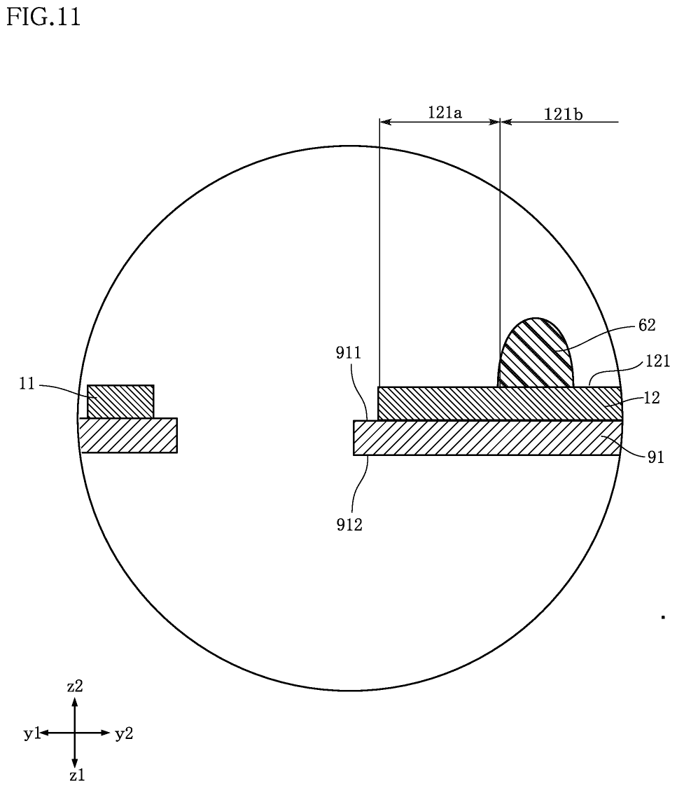

FIG. 10 is an example of a flowchart showing a method for manufacturing the semiconductor device A10. FIGS. 11 to 14 are partially enlarged cross-sectional views each showing a step of the method for manufacturing the semiconductor device A10, and correspond to FIG. 7. Note that the x direction, the y direction, and the z direction shown in FIGS. 11 to 14 correspond to those shown in FIGS. 1 to 7.

As shown in FIG. 10, the method for manufacturing the semiconductor device A10 includes a lead frame forming step S10, a die bonding step S20, a wire bonding step S30, a damming resin forming step S40, a transparent resin forming step S50, a white resin forming step S60, a sealing resin forming step S70, and a cutting step S80.

The lead frame formation step S10 is a step of forming a lead frame from a metal plate. In this step, a metal plate, from which a lead frame will be formed, is prepared first. Then, the metal plate undergoes a process such as punching or etching to form a lead frame 91. The lead frame 91 has an obverse surface 911 and a reverse surface 912 facing away from each other in the z direction (see FIG. 11).

The die bonding step S20 is a step of bonding the light-emitting element 11 and the light-receiving element 12 to the lead frame 91. In this step, the light-emitting element 11 is bonded to the portion of the obverse surface 911 of the lead frame 91 that will be formed into the first die pad 211, via a bonding material (see FIG. 11). Furthermore, the light-receiving element 12 is bonded to the portion of the obverse surface 911 of the lead frame 91 that will be formed into the second die pad 221, via the bonding material (see FIG. 11). The method for bonding the light-emitting element 11 and the light-receiving element 12 in the die bonding step S20 is not particularly limited.

The wire bonding step S30 is a step of forming the wires 4. In this step, the wire 41 is bonded to the cathode electrode of the light-emitting element 11, and to the portion of the obverse surface 911 of the lead frame 91 that will be formed into the pad section 231. Each of the wires 42 to 45 is bonded to an electrode of the light-receiving element 12, and to a predetermined position on the obverse surface 911 of the lead frame 91. The method for forming the wires 4 in the wire bonding step S30 is not particularly limited.

The damming resin forming step S40 is a step of forming the white resin 62. In this step, as shown in FIG. 11, the white resin 62 is formed by potting and curing the material of the white resin 62 with respect to the obverse surface 121 of the light-receiving element 12 bonded to the obverse surface 911 of the lead frame 91. The white resin 62 is formed so as not to cover the light-receiving section 121a of the light-receiving element 12.

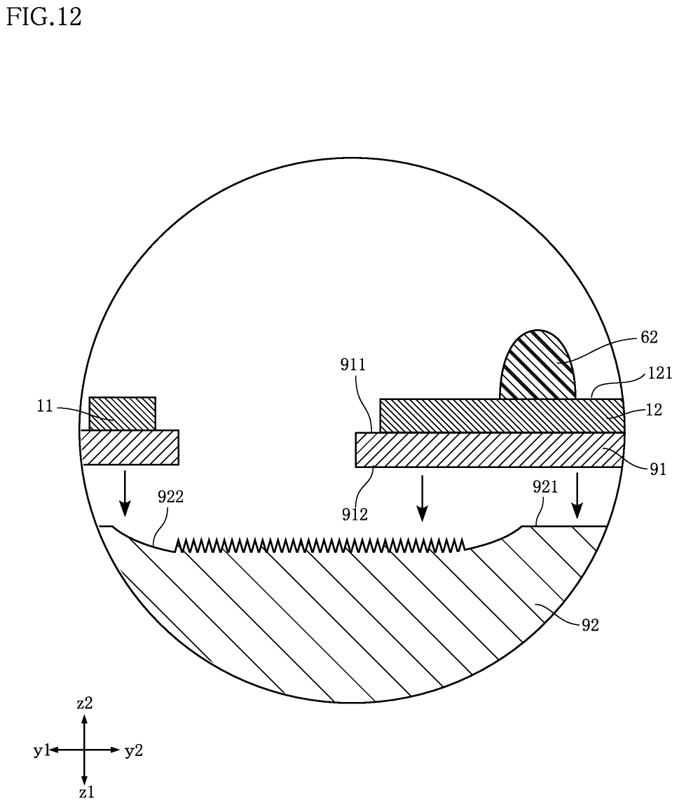

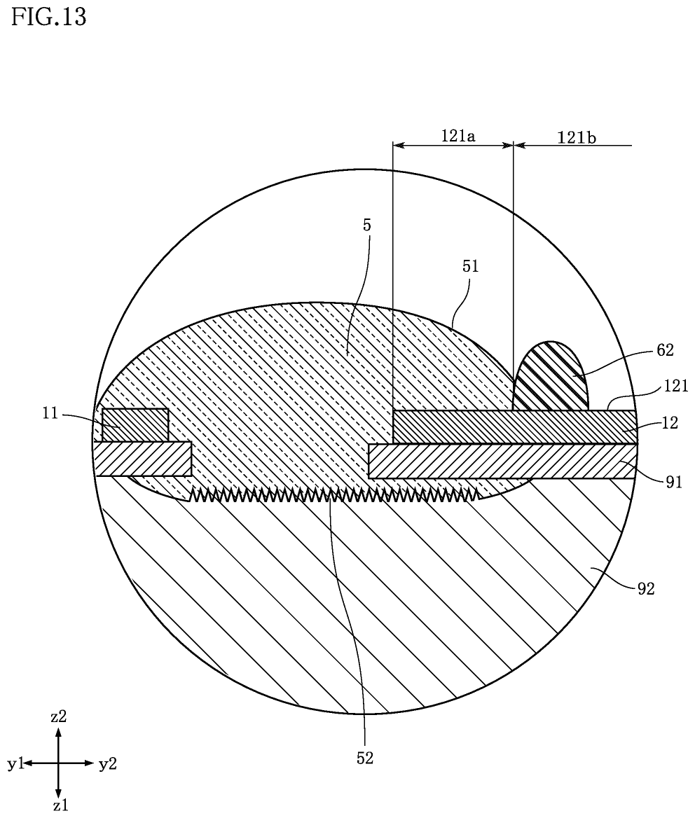

The transparent resin forming step S50 is a step of forming the transparent resin 5. As shown in FIG. 12, this step begins by placing the lead frame 91 with the reverse surface 912 down on a mounting surface 921 of a mold 92. The mold 92 includes a recess 922 recessed from the mounting surface 921 to the z1 side in the z direction. The recess 922 includes a portion located between the light-emitting element 11 and the light-receiving element 12 as viewed in the z direction. The recess 922 has irregularities formed thereon. Next, as shown in FIG. 13, the transparent resin 5 is formed by potting the material of the transparent resin 5 from the obverse surface 911 side of the lead frame 91 (the z2 side in the z direction) and curing the material. The material of the transparent resin 5 is potted to cover the entirety of the light-emitting element 11 and a portion of the light-receiving element 12. At this point, the white resin 62 holds back the flow of the material of the transparent resin 5, thus allowing the transparent resin 5 to cover the light-receiving section 121a and not to cover the circuit forming section 121b. The transparent-resin reverse surface 52 of the transparent resin 5 is formed to have the shape defined by the recess 922 of the mold 92. Accordingly, the transparent-resin reverse surface 52 has irregularities formed thereon. On the other hand, the transparent-resin obverse surface 51 of the transparent resin 5 is a smooth curved surface having a dome shape bulging to the z2 side in the z direction due to the surface tension of the material of the transparent resin 5 in potting. The viscosity and dripping amount of the material of the transparent resin 5 are adjusted so that the transparent-resin obverse surface 51 will have a desired shape.

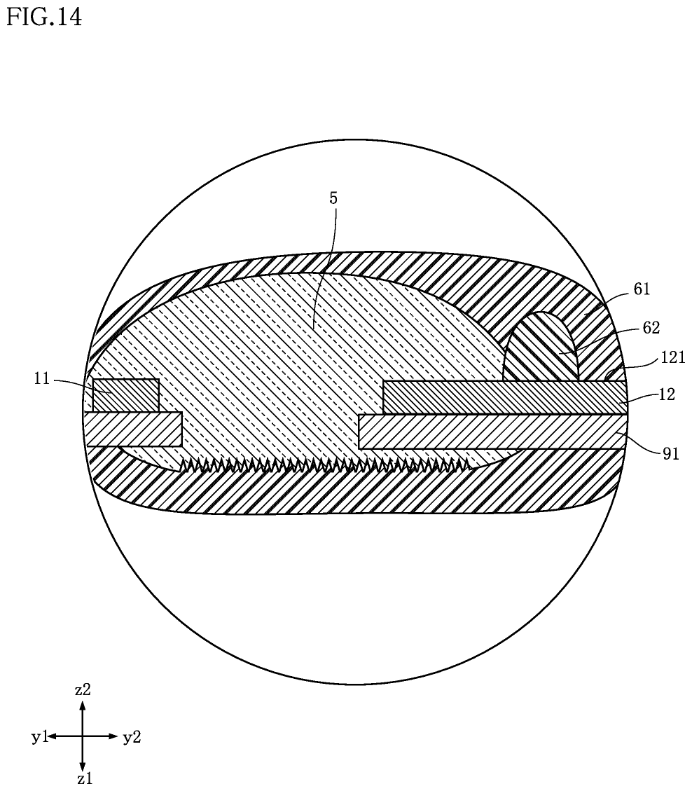

The white resin forming step S60 is a step of forming the white resin 61. In this step, as shown in FIG. 14, the white resin 61 is formed by potting the material of the white resin 61 to cover the entirety of the transparent resin 5 and curing the material. The surface of the white resin 61 is formed into a smooth curved surface due to the surface tension of the material of the white resin 61 in potting. The viscosity and dripping amount of the material of the white resin 61 are adjusted so that the white resin 61 will have a desired shape.

The sealing resin forming step S70 is a step of forming the sealing resin 7. In this step, the material of the sealing resin 7 is cured to form the sealing resin 7 that covers a portion of the lead frame 91, and the entirety of each of the light-emitting element 11, the light-receiving element 12, the wires 4, the transparent resin 5, and the white resins 61 and 62. The step is performed by transfer molding with a mold, for example. Specifically, the lead frame 91 having the white resin 61 formed thereon is set in a molding machine. Next, the fluidized material of the sealing resin 7 is poured into the cavity in the mold, and then is molded and cured. As a result, the sealing resin 7 is formed. Note that the method for forming the sealing resin 7 in the sealing resin forming step S70 is not particularly limited.

The cutting step S80 is a step of cutting the lead frame 91. In this step, the lead frame 91 is cut into pieces by using a blade or the like. In this way, a piece that serves as the semiconductor device A10 is obtained. The cutting method in the cutting step S80 is not particularly limited. Next, the portion of each of the terminal sections 212, 222, 232, 242, 252, 262, 272, and 282 that is exposed from the sealing resin 7 is bent. The semiconductor device A10 as described above is manufactured through the above steps.

The following describes the advantages of the semiconductor device A10.

According to the present embodiment, the transparent-resin reverse surface 52 has irregularities formed thereon. Accordingly, the distance of the interface (hereinafter “reverse-side interface”) between the transparent-resin reverse surface 52 and the white resin 61, in the area between the first die pad 211 and the second die pad 221, is large as compared to the case without the irregularities. This improves the dielectric strength of the semiconductor device A10. Furthermore, the transparent resin 5 includes a portion located on the z1 side in the z direction relative to the reverse surface 211b and the reverse surface 221b, between the first die pad 211 and the second die pad 221 as viewed in the z direction. Accordingly, the distance of the reverse-side interface is larger than that in the case where the transparent-resin reverse surface 52 is flush with the reverse surface 211b and the reverse surface 221b. This further improves the dielectric strength of the semiconductor device A10. Furthermore, the transparent resin 5 covers a portion of each of the reverse surface 211b and the reverse surface 221b. Accordingly, the distance of the reverse-side interface is larger than that in the case where the transparent-resin reverse surface 52 does not cover the reverse surface 211b or the reverse surface 221b. This further improves the dielectric strength of the semiconductor device A10.

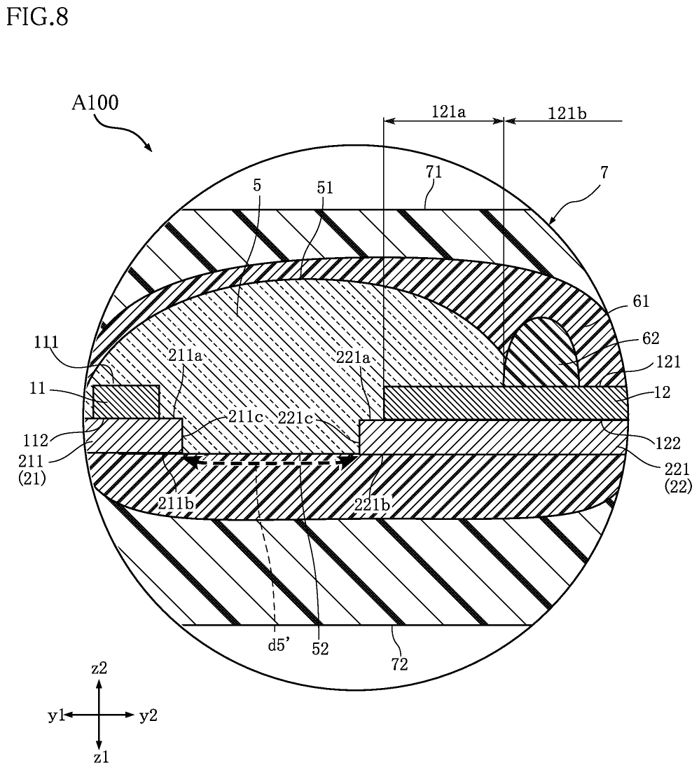

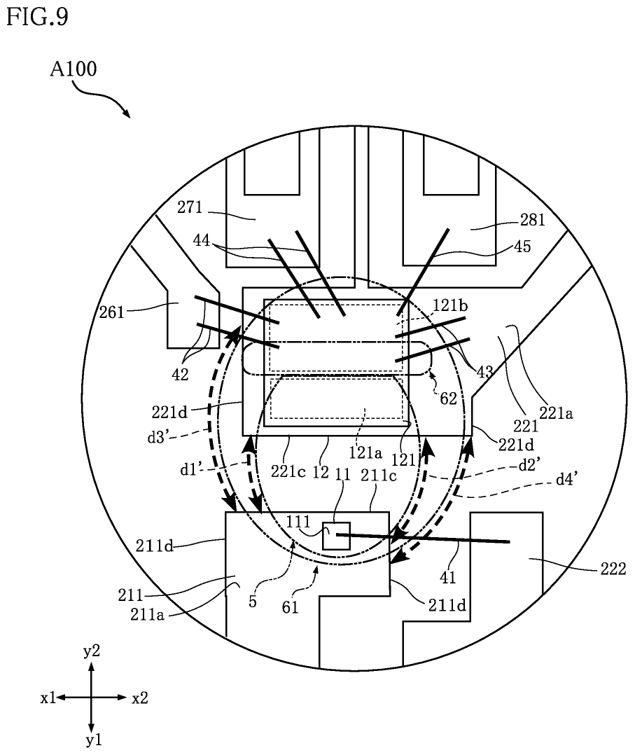

FIGS. 8 and 9 show a conventional semiconductor device A100 for comparison. FIG. 8 is a partially enlarged cross-sectional view showing the semiconductor device A100, and corresponds to FIG. 7. FIG. 9 is a partially enlarged cross-sectional view showing the semiconductor device A100, and corresponds to FIG. 3. The semiconductor device A100 is different from the semiconductor device A10 in the shape of the transparent resin 5. As shown in FIG. 8, the transparent-resin reverse surface 52 in the semiconductor device A100 is flush with the reverse surface 211b and the reverse surface 221b. Since the reverse-side interface (see a bold arrow d5′ in FIG. 8) is linear, the distance of the reverse-side interface is short. The transparent resin 5 in the semiconductor device A10 has the configuration described above, and therefore the distance of the reverse-side interface (see a bold arrow d5 in FIG. 7) is larger than the reverse-side interface (see the bold arrow d5′ in FIG. 8) in the semiconductor device A100. This improves the dielectric strength of the semiconductor device A10.

According to the present embodiment, the transparent resin 5 has an elliptical (or substantially elliptical) shape elongated in the x direction as viewed in the z direction. Thus, as compared to the case where the transparent resin 5 has a circular shape or an elliptical (or substantially elliptical) shape elongated in the y direction, the present embodiment may have the following advantages (see the bold arrows d1, d2 in FIG. 3). As illustrated, the interface defined between the transparent resin 5 and the white resin 61 includes a pair of segments of interface (referred to as “lateral-side interfaces”) located on the mutually opposite sides in the x direction and bridging between the first die pad 211 and the second die pad 221, and the distance or length of the respective segmental interfaces can be large. In particular, according to the present embodiment, the transparent resin 5 entirely covers the opposing surface 211c of the first die pad 211 and the opposing surface 221c of the second die pad 221. Thus, each of the lateral-side interfaces is connected to a side surface 211d of the first die pad 211 and a side surface 221d of the second die pad 221. On the other hand, as shown in FIG. 9, the opposing surface 211c of the first die pad 211 and the opposing surface 221c of the second die pad 221 in the comparative semiconductor device A100 include portions not covered with the transparent resin 5. In FIG. 9, the lateral-side interface (see the bold arrow d1′ in FIG. 9) on the x1 side in the x direction is connected to the opposing surface 211c of the first die pad 211 and the opposing surface 221c of the second die pad 221. The lateral-side interface (see the bold arrow d2′ in FIG. 9) on the x2 side in the x direction is connected to the side surface 211d of the first die pad 211 on the x2 side in the x direction and the opposing surface 221c of the second die pad 221. As described above, the transparent resin 5 in the semiconductor device A10 entirely covers the opposing surface 211c and the opposing surface 221c, so that the distance of each of the lateral-side interfaces (see the bold arrows d1 and d2 in FIG. 3) in the semiconductor device A10 is larger than the distance of each of the lateral-side interfaces (see the bold arrows d1′ and d2′ in FIG. 9) in the semiconductor device A100. This improves the dielectric strength of the semiconductor device A10.

According to the present embodiment, the white resin 61 has an elliptical (or substantially elliptical) shape elongated in the x direction as viewed in the z direction. Thus, as compared to the case where the white resin 61 has a circular shape or an elliptical (or substantially elliptical) shape elongated in the y direction as viewed in the z direction, the present embodiment may have the following advantages. As illustrated, the interface defined between the white resin 61 and the sealing resin 7 includes a pair of segments of interface located on the mutually opposite sides in the x direction and bridging between the conductive supporting member 2 on the input side (the first die pad 211 and the pad section 231 of the lead 23) and the conductive supporting member 2 on the output side (the second die pad 221 and the pad section 261 of the lead 26), and the distance or length of the respective segmental interfaces can be large. In comparison between FIG. 3 and FIG. 9, the semiconductor device A10 is configured such that the distance or length of the interface segment (see the bold arrow d3 in FIG. 3) between the white resin 61 and the sealing resin 7 and located on the x1 side in the x direction can be larger than that of the corresponding interface segment (see the bold arrow d3′ in FIG. 9) in the semiconductor device A100. Furthermore, the semiconductor device A10 is configured such that the distance or length of the interface segment (see the bold arrow d4 in FIG. 3) between the white resin 61 and the sealing resin 7 and located on the x2 side in the x direction can be larger than that of the corresponding interface segment (see the bold arrow d4′ in FIG. 9) in the semiconductor device A100. This improves the dielectric strength of the semiconductor device A10.

In the light-receiving element 12 according to the present embodiment, the light-receiving section 121a is covered with the transparent resin 5, and the circuit forming section 121b is covered with the white resin 61 or the white resin 62. Thus, the light-receiving section 121a can receive light appropriately from the light-emitting element 11 via the transparent resin 5. The circuit forming section 121b is not irradiated with the light emitted from the light-emitting element 11. As such, a circuit formed in the circuit forming section 121b is less likely to suffer from degradation due to light. According to the present embodiment, the white resin 62 is formed before the formation of the transparent resin 5, so that the white resin 62 does not cover the light-receiving section 121a. Then, when the transparent resin 5 is formed, the white resin 62 holds back the fluidized material of the transparent resin 5. Thus, the transparent resin 5 is formed to cover the light-receiving section 121a and not to cover the circuit forming section 121b.

According to the present embodiment, the transparent resin 5 is formed by arranging the mold 92 on a surface of the lead frame 91 on the z1 side in the z direction and potting the material of the transparent resin 5 from the obverse surface 911 side (the z2 side in the z direction) of the lead frame 91. When the transparent resin 5 is formed by potting without the mold 92, it is difficult to adjust the transparent resin 5 into a desired shape. In particular, when the dome-shaped bulging portion is formed on the side of the obverse surface 911 of the lead frame 91, it is difficult to adjust the shape of the portion on the side of the reverse surface 912 of the lead frame 91. In addition, the portion on the side of the reverse surface 912 of the lead frame 91 will have a smooth curved surface due to the surface tension of the material of the transparent resin 5. In the present embodiment, the mold 92 is used so that the shape of the transparent-resin reverse surface 52 of the transparent resin 5 is defined by the recess 922 and formed into a desired shape.

According to the present embodiment, a portion of each of the terminal sections 242, 212, 232, and 252 is exposed from the resin side surface 75. A portion of each of the terminal sections 262, 272, 282, and 222 is exposed from the resin side surface 76. On the other hand, the conductive supporting member 2 is not exposed from the resin top surface 71, the resin bottom surface 72, the resin side surface 73, or the resin side surface 74. In other words, there is no metal portion of the conductive supporting member 2 exposed from the sealing resin 7 between an input-side terminal and an output-side terminal that have large potential differences. This makes it possible to lengthen the insulation distance between an input-side terminal and an output-side terminal (the insulation distance referring to the creepage distance obtained by connecting the portion of the input-side terminal exposed from the sealing resin 7 to the portion of the output-side terminal exposed from the sealing resin 7 along the surface of the sealing resin 7). Thus, the semiconductor device A10 has improved dielectric strength as compared to the case where a portion of the conductive supporting member 2, such as a support lead, is exposed from the resin side surface 73 or the resin side surface 74.

Although the present embodiment has been described with an example where the semiconductor device A10 includes the white resins 61 and 62, the present disclosure is not limited to this. It is possible to omit the white resin 61 and cover the transparent resin 5 with the sealing resin 7. Furthermore, the white resin 62 is not absolutely necessary.

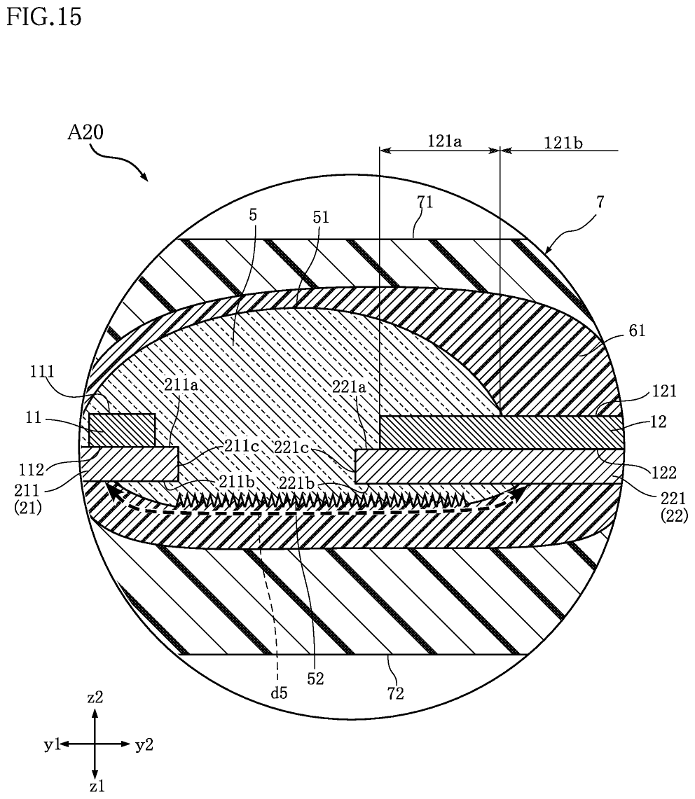

FIGS. 15 to 19 show the other embodiments of the present disclosure. In these figures, elements that are the same as or similar to the elements in the above embodiment are provided with the same reference numerals, and descriptions thereof are omitted.

### Second Embodiment

FIG. 15 is a view for explaining a semiconductor device A20 according to a second embodiment of the present disclosure. FIG. 15 is a partially enlarged cross-sectional view showing the semiconductor device A20, and corresponds to FIG. 7. The semiconductor device A20 according to the present embodiment is different from the semiconductor device A10 according to the first embodiment in not including the white resin 62. The configurations and operations of other parts of the present embodiment are the same as those of the first embodiment. The present embodiment may be combined with any part of the first embodiment.

According to the present embodiment, the semiconductor device A20 does not include the white resin 62. In the semiconductor device A20, the viscosity and dripping amount of the material of the transparent resin 5 are adjusted so that the transparent resin 5 does not cover the circuit forming section 121b of the light-receiving element 12.

According to the present embodiment, the transparent-resin reverse surface 52 also have irregularities. Furthermore, the transparent resin 5 includes a portion located on the z1 side in the z direction relative to the reverse surface 211b and the reverse surface 221b, between the first die pad 211 and the second die pad 221 as viewed in the z direction. Furthermore, the transparent resin 5 covers a portion of each of the reverse surface 211b and the reverse surface 221b. In the semiconductor device A20, the distance of the reverse-side interface is larger than that in the semiconductor device A100. Thus, the semiconductor device A20 has improved dielectric strength. According to the present embodiment, the transparent resin 5 is formed by arranging the mold 92 on the surface of the lead frame 91 on the z1 side in the z direction and potting the material of the transparent resin 5 from the obverse surface 911 side of the lead frame 91. Thus, the shape of the transparent-resin reverse surface 52 of the transparent resin 5 is defined by the recess 922 and formed into a desired shape. Furthermore, the semiconductor device A20 has configurations similar to the semiconductor device A10, whereby the semiconductor device A20 also has advantages owing to the configurations.

### Third Embodiment

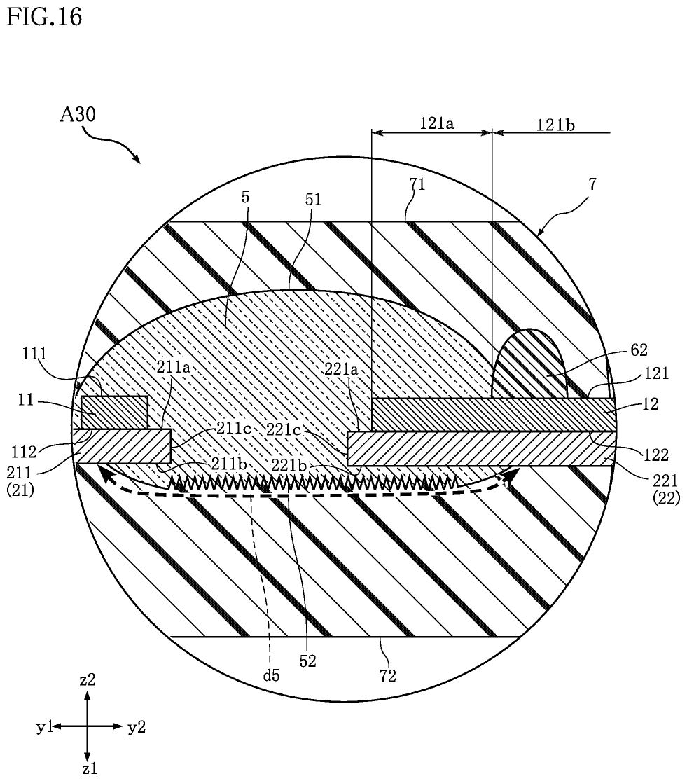

FIG. 16 is a view for explaining a semiconductor device A30 according to a third embodiment of the present disclosure. FIG. 16 is a partially enlarged cross-sectional view showing the semiconductor device A30, and corresponds to FIG. 7. The semiconductor device A30 according to the present embodiment is different from the semiconductor device A10 according to the first embodiment in not including the white resin 61. The configurations and operations of other parts of the present embodiment are the same as those of the first embodiment. The present embodiment may be combined with any part of the first and second embodiments.

According to the present embodiment, the semiconductor device A30 does not include the white resin 61. In the semiconductor device A30, the transparent resin 5 is covered with the sealing resin 7 instead of with the white resin 61. The light emitted by the light-emitting element 11 is reflected at the interface between the transparent resin 5 and the sealing resin 7, and is received by the light-receiving element 12. As with the semiconductor device A20, the semiconductor device A30 may not include the white resin 62.

According to the present embodiment, the transparent-resin reverse surface 52 also has irregularities formed thereon. Furthermore, the transparent resin 5 includes a portion located on the z1 side in the z direction relative to the reverse surface 211b and the reverse surface 221b, between the first die pad 211 and the second die pad 221 as viewed in the z direction. Furthermore, the transparent resin 5 covers a portion of each of the reverse surface 211b and the reverse surface 221b. In the semiconductor device A30, the distance of the reverse-side interface is larger than that in the semiconductor device A100. Thus, the semiconductor device A30 has improved dielectric strength. According to the present embodiment, the transparent resin 5 is formed by arranging the mold 92 on the surface of the lead frame 91 on the z1 side in the z direction and potting the material of the transparent resin 5 from the obverse surface 911 side of the lead frame 91. Thus, the shape of the transparent-resin reverse surface 52 of the transparent resin 5 is defined by the recess 922 and formed into a desired shape. Furthermore, the semiconductor device A30 has configurations similar to the semiconductor device A10, whereby the semiconductor device A30 also has advantages owing to the configurations.

### Fourth Embodiment

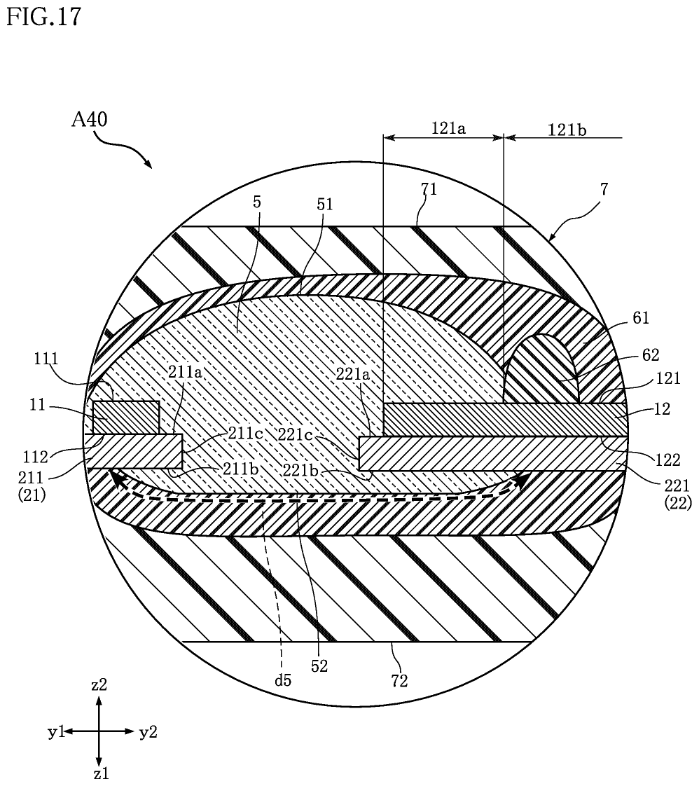

FIG. 17 is a view for explaining a semiconductor device A40 according to a fourth embodiment of the present disclosure. FIG. 17 is a partially enlarged cross-sectional view showing the semiconductor device A40, and corresponds to FIG. 7. The semiconductor device A40 according to the present embodiment is different from the semiconductor device A10 according to the first embodiment in that the transparent-resin reverse surface 52 does not have any irregularities. The configurations and operations of other parts of the present embodiment are the same as those of the first embodiment. The present embodiment may be combined with any part of the first to third embodiments.

According to the present embodiment, the transparent-resin reverse surface 52 of the transparent-resin reverse surface 52 does not have any irregularities. The transparent resin 5 is formed by using the mold 92 having the recess 922 with no irregularities.

In the present embodiment, the transparent resin 5 also similarly includes a portion located on the z1 side in the z direction relative to the reverse surface 211b and the reverse surface 221b, between the first die pad 211 and the second die pad 221 as viewed in the z direction. Furthermore, the transparent resin 5 covers a portion of each of the reverse surface 211b and the reverse surface 221b. In the semiconductor device A40, the distance of the reverse-side interface is larger than that in the semiconductor device A100. Thus, although the transparent-resin reverse surface 52 does not have any irregularities, the semiconductor device A40 has improved dielectric strength. According to the present embodiment, the transparent resin 5 is formed by arranging the mold 92 on the surface of the lead frame 91 on the z1 side in the z direction and potting the material of the transparent resin 5 from the obverse surface 911 side of the lead frame 91. Thus, the shape of the transparent-resin reverse surface 52 of the transparent resin 5 is defined by the recess 922 and formed into a desired shape. Furthermore, the semiconductor device A40 has configurations similar to the semiconductor device A10, whereby the semiconductor device A40 also has advantages owing to the configurations.

### Fifth Embodiment

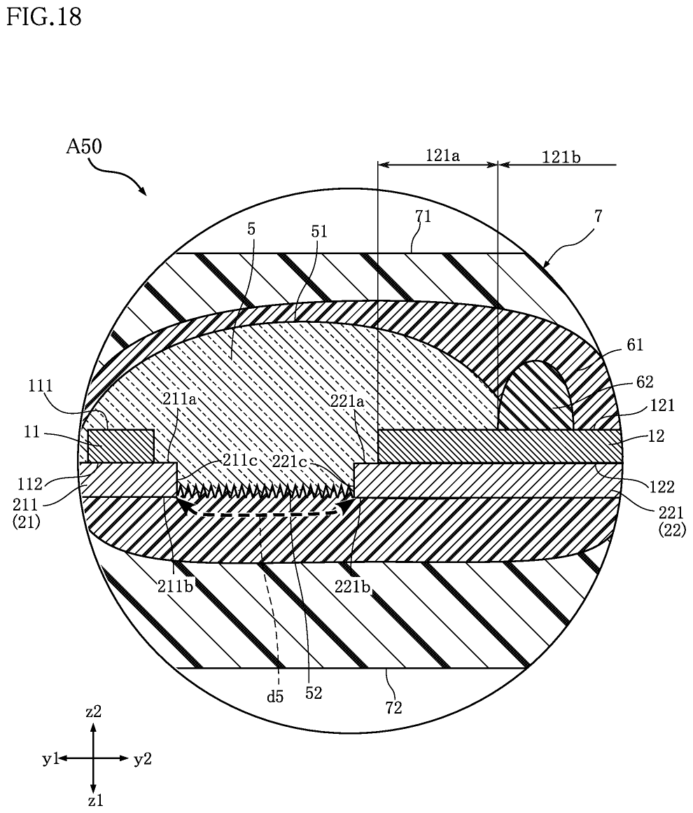

FIG. 18 is a view for explaining a semiconductor device A50 according to a fifth embodiment of the present disclosure. FIG. 18 is a partially enlarged cross-sectional view showing the semiconductor device A50, and corresponds to FIG. 7. The semiconductor device A50 according to the present embodiment is different from the semiconductor device A10 according to the first embodiment in the shape of the transparent resin 5. The configurations and operations of other parts of the present embodiment are the same as those of the first embodiment. The present embodiment may be combined with any part of the first to fourth embodiments.

The transparent resin 5 according to the present embodiment does not include a portion located on the z1 side in the z direction relative to the reverse surface 211b and the reverse surface 221b, between the first die pad 211 and the second die pad 221 as viewed in the z direction. Furthermore, the transparent resin 5 does not include a portion that partially covers the reverse surface 211b or the reverse surface 221b. The transparent resin 5 is formed by using the mold 92 not formed with the recess 922 and having the mounting surface 921 formed with irregularities.

According to the present embodiment, the transparent-resin reverse surface 52 also has irregularities. Thus, in the semiconductor device A50, the distance of the reverse-side interface is larger than that in the semiconductor device A100, which allows the semiconductor device A50 to have improved dielectric strength. According to the present embodiment, the transparent resin 5 is formed by arranging the mold 92 on the surface of the lead frame 91 on the z1 side in the z direction and potting the material of the transparent resin 5 from the obverse surface 911 side of the lead frame 91. Thus, the shape of the transparent-resin reverse surface 52 of the transparent resin 5 is defined by the mold 92 and formed into a desired shape. Furthermore, the semiconductor device A50 has configurations similar to the semiconductor device A10, whereby the semiconductor device A50 also has advantages owing to the configurations. Furthermore, according to the semiconductor device A50 in the present embodiment, the transparent resin 5 is not formed on the side of the reverse surface 211b and the reverse surface 221b, which makes it possible to reduce the dimension of the sealing resin 7 in the z direction.

### Sixth Embodiment

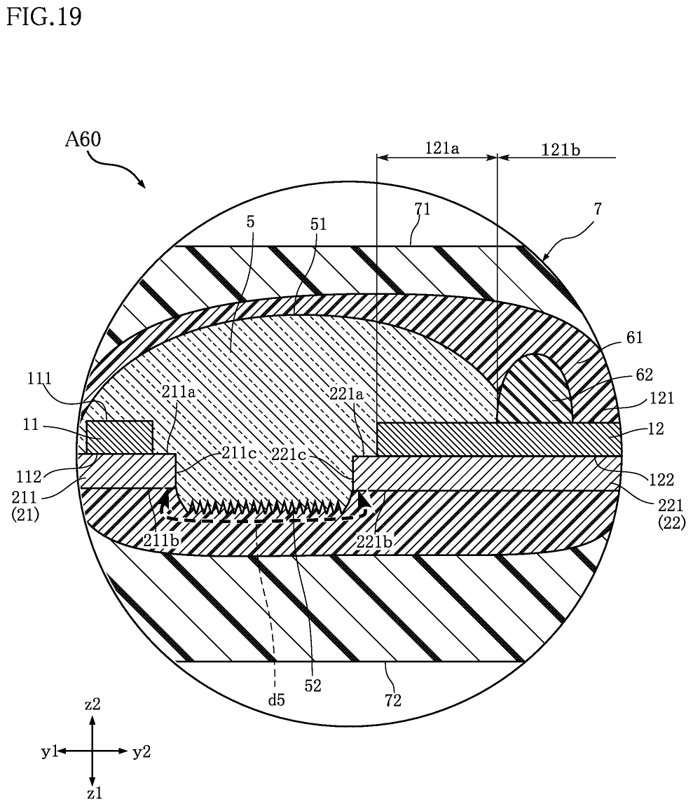

FIG. 19 is a view for explaining a semiconductor device A60 according to a sixth embodiment of the present disclosure. FIG. 19 is a partially enlarged cross-sectional view showing the semiconductor device A60, and corresponds to FIG. 7. The semiconductor device A60 according to the present embodiment is different from the semiconductor device A10 according to the first embodiment in the shape of the transparent resin 5. The configurations and operations of other parts of the present embodiment are the same as those of the first embodiment. The present embodiment may be combined with any part of the first to fifth embodiments.

The transparent resin 5 according to the present embodiment does not include a portion that partially covers the reverse surface 211b or the reverse surface 221b. In other words, the transparent resin 5 does not cover the reverse surface 211b or the reverse surface 221b.

In the present embodiment, the transparent resin 5 also similarly includes a portion located on the z1 side in the z direction relative to the reverse surface 211b and the reverse surface 221b, between the first die pad 211 and the second die pad 221 as viewed in the z direction. The transparent-resin reverse surface 52 has irregularities. In the semiconductor device A60, the distance of the reverse-side interface is larger than that in the semiconductor device A100. Thus, although the transparent resin 5 does not cover the reverse surface 211b or the reverse surface 221b, the semiconductor device A60 has improved dielectric strength. According to the present embodiment, the transparent resin 5 is formed by arranging the mold 92 on the surface of the lead frame 91 on the z1 side in the z direction and potting the material of the transparent resin 5 from the obverse surface 911 side of the lead frame 91. Thus, the shape of the transparent-resin reverse surface 52 of the transparent resin 5 is defined by the mold 92 and formed into a desired shape. Furthermore, the semiconductor device A60 has configurations similar to the semiconductor device A10, whereby the semiconductor device A60 also has advantages owing to the configurations.

As described in the first embodiment and the fourth to sixth embodiments, the shape of the transparent-resin reverse surface 52 of each of the semiconductor devices A10, A40, A50, and A60 can be adjusted freely by changing the design of the mold 92.

### Seventh Embodiment

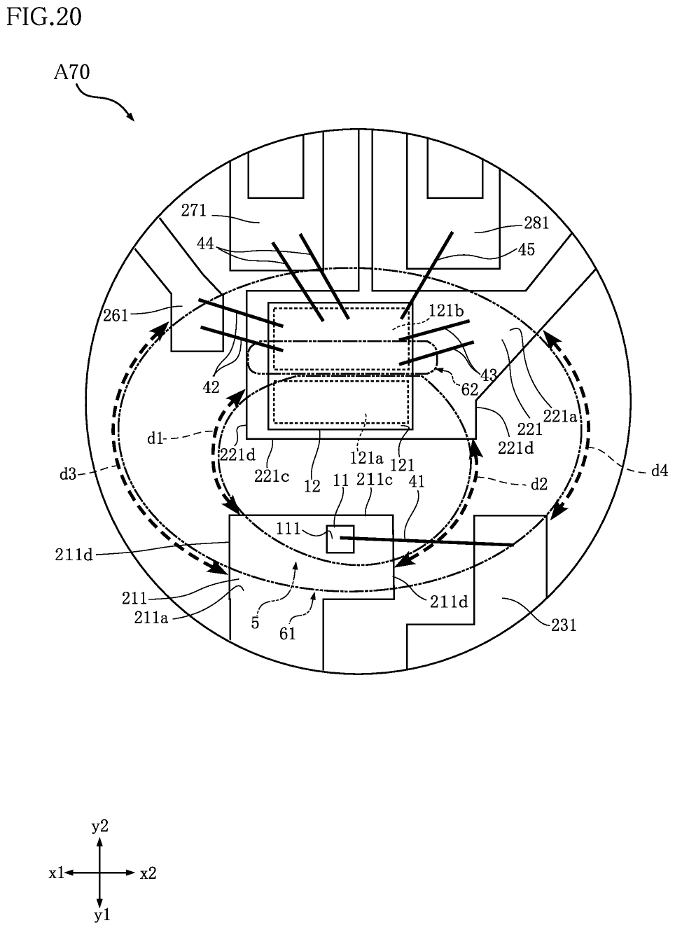

FIG. 20 is a view for explaining a semiconductor device A70 according to a seventh embodiment of the present disclosure. FIG. 20 is a partially enlarged cross-sectional view showing the semiconductor device A70, and corresponds to FIG. 3. For convenience of understanding, FIG. 20 shows the transparent resin 5, the white resins 61 and 62, and the sealing resin 7 in phantom, and the outer shape of each resin is indicated by an imaginary line (two-dot chain line). The semiconductor device A70 according to the present embodiment is different from the semiconductor device A10 according to the first embodiment in the shape of the transparent resin 5. The configurations and operations of other parts of the present embodiment are the same as those of the first embodiment. The present embodiment may be combined with any part of the first to sixth embodiments.

According to the present embodiment, the opposing surface 211c of the first die pad 211 is not entirely covered with the transparent resin 5, but is partially covered with the white resin 61. The opposing surface 221c of the second die pad 221 is also not entirely covered with the transparent resin 5, and is partially covered with the white resin 61. In other words, the transparent resin 5 only covers a portion of each of the opposing surface 211c and the opposing surface 221c. The lateral-side interface on the x1 side in the x direction is connected to the opposing surface 211c of the first die pad 211 and one of the side surfaces 221d of the second die pad 221 (see a bold arrow d1 in FIG. 20). The lateral-side interface on the x2 side in the x direction is connected to one of the side surfaces 211d of the first die pad 211 and the opposing surface 221c of the second die pad 221 (see a bold arrow d2 in FIG. 20). However, as with the semiconductor device A10 according to the first embodiment, the lateral-side interfaces protrude outward from the two side surfaces 211d of the first die pad 211.

According to the present embodiment, the transparent-resin reverse surface 52 also has irregularities. Furthermore, the transparent resin 5 includes a portion located on the z1 side in the z direction relative to the reverse surface 211b and the reverse surface 221b, between the first die pad 211 and the second die pad 221 as viewed in the z direction. Furthermore, the transparent resin 5 covers a portion of each of the reverse surface 211b and the reverse surface 221b. In the semiconductor device A70, the distance of the reverse-side interface is larger than that in the semiconductor device A100. Thus, the semiconductor device A70 has improved dielectric strength.

According to the present embodiment, the transparent resin 5 does not entirely cover the opposing surface 211c of the first die pad 211 and the opposing surface 221c of the second die pad 221, but the lateral-side interfaces protrude outward from the two side surfaces 211d of the first die pad 211. Accordingly, the distance of each of the lateral-side interfaces (see the bold arrows d1 and d2 in FIG. 20) is larger than the distance of each of the lateral-side interfaces (see the bold arrows d1′ and d2′ in FIG. 9) in the semiconductor device A100. This improves the dielectric strength of the semiconductor device A70.

According to the present embodiment, the transparent resin 5 is formed by arranging the mold 92 on the surface of the lead frame 91 on the z1 side in the z direction and potting the material of the transparent resin 5 from the obverse surface 911 side of the lead frame 91. Thus, the shape of the transparent-resin reverse surface 52 of the transparent resin 5 is defined by the recess 922 and formed into a desired shape. Furthermore, the semiconductor device A70 has configurations similar to the semiconductor device A10, whereby the semiconductor device A70 also has advantages owing to the configurations.

The semiconductor device and the method for manufacturing the semiconductor device according to the present disclosure are not limited to the above embodiments. Various design changes can be made to the specific configurations of the elements of the semiconductive device according to the present disclosure, and to the specific processes in the operations in the method for manufacturing the semiconductor device according to the present disclosure. The present disclosure covers the embodiments according to the following clauses.
Clause 1. (FIG. 7)
A semiconductor device comprising:
a first lead (21) including a first die pad (211) having a first obverse surface (211a) and a first reverse surface (211b) facing away from each other in a thickness direction (z direction);
a second lead (22) including a second die pad (221) having a second obverse surface (221a) facing a same side as the first obverse surface in the thickness direction and a second reverse surface (221b) facing a same side as the first reverse surface in the thickness direction;
a light-emitting element (11) mounted on the first obverse surface;
a light-receiving element (12) mounted on the second obverse surface;
a transparent resin (5) covering at least a portion of each of the light-emitting element and the light-receiving element; and
a first resin (61) covering the transparent resin,
wherein the transparent resin includes a transparent-resin obverse surface (51) facing a same side as the first obverse surface in the thickness direction, and a transparent-resin reverse surface (52) facing a same side as the first reverse surface in the thickness direction, and
the transparent-resin reverse surface has a surface roughness larger than a surface roughness of the transparent-resin obverse surface.
Clause 2.
The semiconductor device according to clause 1, wherein the transparent resin includes a portion offset from the first reverse surface toward a side in which the first reverse surface faces, between the first die pad and the second die pad as viewed in the thickness direction.
Clause 3.
The semiconductor device according to clause 2, wherein the transparent resin covers at least a portion of the first reverse surface and the second reverse surface.
Clause 4. (FIGS. 3 and 7)
The semiconductor device according to any of clauses 1 to 3, wherein a portion of the light-receiving element is exposed from the transparent resin.
Clause 5. (FIGS. 3 and 7)
The semiconductor device according to clause 4, further comprising a second resin (62),
wherein the light-receiving element includes an element obverse surface (121) facing a same side as the first obverse surface, and
the second resin is arranged in contact with the element obverse surface, and is in contact with the transparent resin and the first resin.
Clause 6.

The semiconductor device according to any of clauses 1 to 5, wherein the first resin comprises a white resin.
Clause 7. (FIG. 3)
The semiconductor device according to any of clauses 1 to 6,
wherein the first die pad includes a first opposing surface (211c) facing the second die pad, and two first side surfaces (211d) connected to the first obverse surface, the first reverse surface, and the first opposing surface, and
as viewed in the thickness direction, an interface between the transparent resin and the first resin protrudes outward from the two side surfaces.
Clause 8. (FIG. 3)
The semiconductor device according to clause 7, wherein the transparent resin covers an entirety of the first opposing surface.
Clause 9. (FIG. 3)
The semiconductor device according to any of clauses 1 to 8, wherein the second die pad includes a second opposing surface (221c) facing the first die pad, and
the transparent resin covers an entirety of the second opposing surface.
Clause 10. (FIG. 3)
The semiconductor device according to any of clauses 1 to 9, wherein a first dimension (W1) of the transparent resin in a first direction (y direction), which is a direction that is perpendicular to the thickness direction and in which the light-emitting element and the light-receiving element are aligned, is smaller than a second dimension (W2) of the transparent resin in a second direction (x direction) perpendicular to the thickness direction and the first direction.
Clause 11. (FIG. 3)
The semiconductor device according to clause 10, further comprising a third resin (7) covering an entirety of the first resin,
wherein a third dimension (W3) of the first resin in the first direction is smaller than a fourth dimension (W4) of the first resin in the second direction.
Clause 12. (FIG. 10, FIGS. 12 to 14)
A method for manufacturing a semiconductor device, comprising:
a step (S10) of forming a lead frame (91) including an obverse surface (911) and a reverse surface (912) facing away from each other in a thickness direction;
a step (S20) of bonding a light-emitting element (11) and a light-receiving element (12) to the lead frame;
a step (S50) of forming a transparent resin (5) covering at least a portion of each of the light-emitting element and the light-receiving element; and
a step (S60) of forming a first resin (61) covering the transparent resin,
wherein in the step of forming the transparent resin, a mold (92) is arranged on a back surface side of the lead frame, and a material of the transparent resin is potted from an obverse surface side of the lead frame, and
the mold has a mounting surface (921) on which the lead frame is mounted, and the mounting surface is formed with a recess (922) including a portion located between the light-emitting element and the light-receiving element as viewed in the thickness direction.
Clause 13. (FIG. 12)
The method according to clause 12, wherein the recess has irregularities.
Clause 14. (FIG. 11)
The method according to clause 12 or 13, further comprising a step (S40) of forming a second resin (62) on an element obverse surface of the light-receiving element that faces a same side as the obverse surface of the lead frame, before the step of forming the transparent resin,
wherein in the step of forming the transparent resin, the second resin holds back a flow of the material of the transparent resin.
Clause 15.
The method according to any of clauses 12 to 14, further comprising a step (S70) of forming a third resin (7) to cover the first resin, after the step of forming the first resin,
wherein the first resin is a white resin.

### REFERENCE NUMERALS

A10, A20, A30, A40, A50, A60, A70: Semiconductor device
11: Light-emitting element 111: Obverse surface
112: Reverse surface
12: Light-receiving element 121: Obverse surface
121a: Light-receiving section
121b: Circuit forming section 122: Reverse surface
2: Conductive supporting member
21: Lead 211: First die pad 211a: Obverse surface
211b: Reverse surface 211c: Opposing surface
211d: Side surface
212: Terminal section 22: Lead 221: Second die pad
221a: Obverse surface 221b: Reverse surface
221c: Opposing surface
221d: Side surface 222: Terminal section 23: Lead
231: Pad section 232: Terminal section 24: Lead
242: Terminal section 25: Lead 252: Terminal section
26: Lead 261: Pad section 262: Terminal section
27: Lead 271: Pad section 272: Terminal section
28: Lead 281: Pad section 282: Terminal section
4, 41-45: Wire 5: Transparent resin
51: Transparent-resin obverse surface
52: Transparent-resin reverse surface 61, 62: White resin
7: Sealing resin
71: Resin top surface 72: Resin bottom surface
73-76: Resin side surface
91: Lead frame 911: Obverse surface 912: Reverse surface
92: Mold 921: Mounting surface 922: Recess

1. A semiconductor device comprising:
a first lead including a first die pad having a first obverse surface and a first reverse surface facing away from each other in a thickness direction;
a second lead including a second die pad having a second obverse surface facing a same side as the first obverse surface in the thickness direction and a second reverse surface facing a same side as the first reverse surface in the thickness direction;
a light-emitting element mounted on the first obverse surface;
a light-receiving element mounted on the second obverse surface;
a transparent resin covering at least a portion of each of the light-emitting element and the light-receiving element; and
a first resin covering the transparent resin,
wherein the transparent resin includes a transparent-resin obverse surface facing a same side as the first obverse surface in the thickness direction, and a transparent-resin reverse surface facing a same side as the first reverse surface in the thickness direction, and
the transparent-resin reverse surface has a surface roughness larger than a surface roughness of the transparent-resin obverse surface.

2. The semiconductor device according to claim 1, wherein the transparent resin includes a portion offset from the first reverse surface toward a side in which the first reverse surface faces, between the first die pad and the second die pad as viewed in the thickness direction.

3. The semiconductor device according to claim 2, wherein the transparent resin covers at least a portion of the first reverse surface and the second reverse surface.

4. The semiconductor device according to claim 1, wherein a portion of the light-receiving element is exposed from the transparent resin.

5. The semiconductor device according to claim 4, further comprising a second resin,
wherein the light-receiving element includes an element obverse surface facing a same side as the first obverse surface, and
the second resin is arranged in contact with the element obverse surface, and is in contact with the transparent resin and the first resin.

6. The semiconductor device according to claim 1, wherein the first resin comprises a white resin.

7. The semiconductor device according to claim 1,
wherein the first die pad includes a first opposing surface facing the second die pad, and two first side surfaces connected to the first obverse surface, the first reverse surface, and the first opposing surface, and
as viewed in the thickness direction, an interface between the transparent resin and the first resin protrudes outward from the two side surfaces.

8. The semiconductor device according to claim 7, wherein the transparent resin covers an entirety of the first opposing surface.

9. The semiconductor device according to claim 1,
wherein the second die pad includes a second opposing surface facing the first die pad, and
the transparent resin covers an entirety of the second opposing surface.

10. The semiconductor device according to claim 1, wherein a first dimension of the transparent resin in a first direction that is perpendicular to the thickness direction and in which the light-emitting element and the light-receiving element are aligned is smaller than a second dimension of the transparent resin in a second direction perpendicular to the thickness direction and the first direction.

11. The semiconductor device according to claim 10, further comprising a third resin covering an entirety of the first resin,
wherein a third dimension of the first resin in the first direction is smaller than a fourth dimension of the first resin in the second direction.

12. A method for manufacturing a semiconductor device, comprising:
forming a lead frame including an obverse surface and a reverse surface facing away from each other in a thickness direction;
bonding a light-emitting element and a light-receiving element to the lead frame;
forming a transparent resin covering at least a portion of each of the light-emitting element and the light-receiving element; and
forming a first resin covering the transparent resin,
wherein in forming the transparent resin, a mold is arranged on a back surface side of the lead frame, and a material of the transparent resin is potted from an obverse surface side of the lead frame, and
the mold has a mounting surface on which the lead frame is mounted, and the mounting surface is formed with a recess including a portion located between the light-emitting element and the light-receiving element as viewed in the thickness direction.

13. The method according to claim 12, wherein the recess has irregularities.

14. The method according to claim 12, further comprising forming a second resin on an element obverse surface of the light-receiving element that faces a same side as the obverse surface of the lead frame, before forming the transparent resin,
wherein in forming the transparent resin, the second resin holds back a flow of the material of the transparent resin.

15. The method according to claim 12, further comprising forming a third resin to cover the first resin, after forming the first resin,
wherein the first resin is a white resin.
